(19) United States
(12) Patent Application Publication
(10) Pub. No.: US 2024/0222293 A1
(43) Pub. Date: Jul. 4, 2024

(54) TECHNOLOGIES FOR PACKAGE SUBSTRATES WITH ASYMMETRIC PLATING

(71) Applicant: Intel Corporation, Santa Clara, CA (US)

(72) Inventors: Kristof Darmawikarta, Chandler, AZ (US); Srinivas V. Pietambaram, Chandler, AZ (US); Gang Duan, Chandler, AZ (US); Siddharth Alur Narasimha Krishna, Gilbert, AZ (US); Sameer R. Paital, Mesa, AZ (US); Helme A. Castro De la Torre, Gilbert, AZ (US)

(73) Assignee: Intel Corporation, Santa Clara, CA (US)

(21) Appl. No.: 18/091,616

(22) Filed: Dec. 30, 2022

(51) Int. Cl. H01L 23/58; H01L 21/48; H01L 23/498

(52) U.S. Cl. CPC H01L 23/58; H01L 21/4853; H01L 21/4857; H01L 21/486; H01L 23/49822; H01L 23/49827

(57) ABSTRACT

Technologies for ribbon field-effect transistors with variable fin numbers are disclosed. In an illustrative embodiment, a stack of semiconductor fins is formed, with each semiconductor fin having a source region, a channel region, and a drain region. Some or all of the channel regions can be selectively removed, allowing for the drive and/or leakage current to be tuned. In some embodiments, one or more of the semiconductor fins near the top of the stack can be removed. In other embodiments, one or more of the semiconductor fins at or closer to the bottom of the stack can be removed.

### BACKGROUND

As transistor density increases, interconnect density for connections between dies and substrates is increasing as well. Interconnect design in substrate packages can improve power delivery and overall system performance. Thinner traces can provide more density, but thinner traces can carry less current as well as less heat. Thicker traces can carry more current and heat, but thicker traces may be less dense.

### BRIEF DESCRIPTION OF THE DRAWINGS

FIG. 1 is an isometric view of an integrated circuit component.

FIG. 2 is a cross-sectional side view of one embodiment of the integrated circuit component of FIG. 1.

FIG. 3 is a simplified flow diagram of at least one embodiment of a method for manufacturing the substrate of the integrated circuit component of FIG. 1.

FIG. 4 is a cross-sectional side view at one step of the flow diagram of FIG. 3.

FIG. 5 is a cross-sectional side view at one step of the flow diagram of FIG. 3.

FIG. 6 is a cross-sectional side view at one step of the flow diagram of FIG. 3.

FIG. 7 is a cross-sectional side view at one step of the flow diagram of FIG. 3.

FIG. 8 is a cross-sectional side view at one step of the flow diagram of FIG. 3.

FIG. 9 is a cross-sectional side view at one step of the flow diagram of FIG. 3.

FIG. 10 is a cross-sectional side view at one step of the flow diagram of FIG. 3.

FIG. 11 is a cross-sectional side view at one step of the flow diagram of FIG. 3.

FIG. 12 is a cross-sectional side view at one step of the flow diagram of FIG. 3.

FIG. 13 is a cross-sectional side view at one step of the flow diagram of FIG. 3.

FIG. 14 is a cross-sectional side view at one step of the flow diagram of FIG. 3.

FIG. 15 is a cross-sectional side view at one step of the flow diagram of FIG. 3.

FIG. 16 is a cross-sectional side view at one step of the flow diagram of FIG. 3.

FIG. 17 is a cross-sectional side view at one step of the flow diagram of FIG. 3.

FIG. 18 is a cross-sectional side view at one step of the flow diagram of FIG. 3.

FIG. 19 is a cross-sectional side view at one step of the flow diagram of FIG. 3.

FIG. 20 is a cross-sectional side view at one step of the flow diagram of FIG. 3.

FIG. 21 is a cross-sectional side view at one step of the flow diagram of FIG. 3.

FIG. 22 is a cross-sectional side view at one step of the flow diagram of FIG. 3.

FIG. 23 is a cross-sectional side view at one step of the flow diagram of FIG. 3.

FIG. 24 is a cross-sectional side view at one step of the flow diagram of FIG. 3.

FIG. 25 is a cross-sectional side view at one step of the flow diagram of FIG. 3.

FIG. 26 is a cross-sectional side view at one step of the flow diagram of FIG. 3.

FIG. 27 is a cross-sectional side view at one step of the flow diagram of FIG. 3.

FIG. 28 is a cross-sectional side view at one step of the flow diagram of FIG. 3.

FIG. 29 is a cross-sectional side view at one step of the flow diagram of FIG. 3.

FIG. 30 is a cross-sectional side view of one embodiment of the integrated circuit component of FIG. 1.

FIG. 31 is a simplified flow diagram of at least one embodiment of a method for manufacturing the substrate of the integrated circuit component of FIG. 1.

FIG. 32 is a cross-sectional side view at one step of the flow diagram of FIG. 31.

FIG. 33 is a cross-sectional side view at one step of the flow diagram of FIG. 31.

FIG. 34 is a cross-sectional side view at one step of the flow diagram of FIG. 31.

FIG. 35 is a cross-sectional side view at one step of the flow diagram of FIG. 31.

FIG. 36 is a cross-sectional side view at one step of the flow diagram of FIG. 31.

FIG. 37 is a cross-sectional side view of one embodiment of the integrated circuit component of FIG. 1.

FIG. 38 is a cross-sectional top view of one embodiment of the integrated circuit component of FIG. 37.

FIG. 39 is a simplified flow diagram of at least one embodiment of a method for manufacturing the substrate of the integrated circuit component of FIG. 1.

FIG. 40 is a cross-sectional side view at one step of the flow diagram of FIG. 39.

FIG. 41 is a cross-sectional side view at one step of the flow diagram of FIG. 39.

FIG. 42 is a cross-sectional side view at one step of the flow diagram of FIG. 39.

FIG. 44 is a cross-sectional side view at one step of the flow diagram of FIG. 39.

FIG. 45 is a cross-sectional side view of one embodiment of the integrated circuit component of FIG. 1.

FIG. 46 is a cross-sectional top view of one embodiment of the integrated circuit component of FIG. 45.

FIG. 47 is a simplified flow diagram of at least one embodiment of a method for manufacturing the substrate of the integrated circuit component of FIG. 1.

FIG. 48 is a cross-sectional side view at one step of the flow diagram of FIG. 47.

FIG. 49 is a cross-sectional side view at one step of the flow diagram of FIG. 47.

FIG. 50 is a cross-sectional side view at one step of the flow diagram of FIG. 47.

FIG. 51 is a cross-sectional side view at one step of the flow diagram of FIG. 47.

FIG. 52 is a cross-sectional side view at one step of the flow diagram of FIG. 47.

FIG. 53 is a cross-sectional side view at one step of the flow diagram of FIG. 47.

FIG. 54 is a cross-sectional side view at one step of the flow diagram of FIG. 47.

FIG. 55 is a cross-sectional side view at one step of the flow diagram of FIG. 47.

FIG. 56 is a top view of a wafer and dies that may be included in a microelectronic assembly, in accordance with any of the embodiments disclosed herein.

FIG. 57 is a cross-sectional side view of an integrated circuit device that may be included in a microelectronic assembly, in accordance with any of the embodiments disclosed herein.

FIGS. 58A-58D are perspective views of example planar, FinFET, gate-all-around, and stacked gate-all-around transistors.

FIG. 59 is a cross-sectional side view of an integrated circuit device assembly that may include a microelectronic assembly, in accordance with any of the embodiments disclosed herein.

FIG. 60 is a block diagram of an example electrical device that may include a microelectronic assembly, in accordance with any of the embodiments disclosed herein.

### DETAILED DESCRIPTION

Efficient interconnect design in substrate packaging to improve power delivery and overall system performance is an area of interest. One approach for power delivery improvement is to have asymmetric copper plating, with thinner, denser copper plating for the front side that connects to a die and thicker, less dense copper plating for the back side that connects to a higher-level interconnect or motherboard. Traces or power lines with thicker copper plating on the back side layers can serve the purpose of reducing current resistance, increasing maximum current, providing increased heat dissipation lines for thermal management, which improves power delivery, reduces latency, and allows for increase of the overall clock speed.

In one embodiment disclosed herein, as described in more detail below, a substrate for an integrated circuit has one or more layers with thinner copper traces on one part and one or more layers with thicker copper traces on another part. In the illustrative embodiment, the two parts of the substrate are created separately and joined together using a hybrid bond approach. In some embodiments, one part of the substrate is built up on a core. In other embodiments, a core is not used. In some embodiments, a magnetic core increases the inductance of an inductor, allowing for, e.g., improved voltage regulation. In other embodiments, a magnetic core may not be present.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, a substrate assembly feature, such as a through width, that is described as having substantially a listed dimension can vary within a few percent of the listed dimension.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

As used herein, the terms “upper”/“lower” or “above”/“below” may refer to relative locations of an object (e.g., the surfaces described above), especially in light of examples shown in the attached figures, rather than an absolute location of an object. For example, an upper surface of an apparatus may be on an opposite side of the apparatus from a lower surface of the object, and the upper surface may be facing upward generally only when viewed in a particular way. As another example, a first object above a second object may be on or near an “upper” surface of the second object rather than near a “lower” surface of the object, and the first object may be truly above the second object only when the two objects are viewed in a particular way.

References are made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document. Different parts of the drawings with the same hatchings refer to the same component or material unless labeled otherwise.

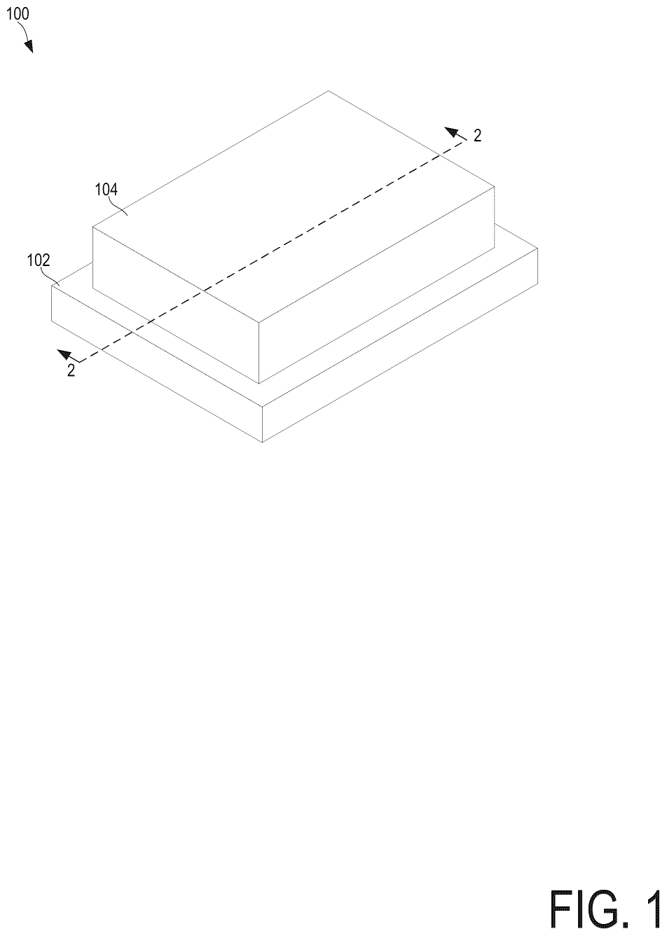

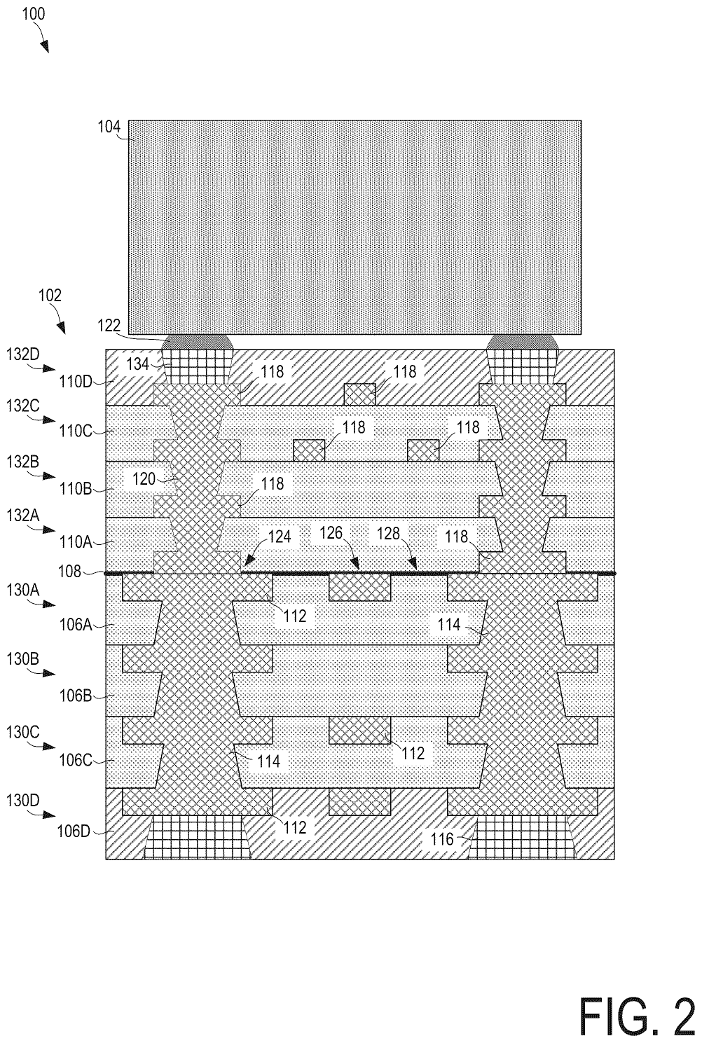

Referring now to FIGS. 1 and 2, in one embodiment, FIG. 1 shows one perspective view of an integrated circuit component 100. FIG. 2 shows a cross-sectional view of the integrated circuit component 100. The integrated circuit component 100 includes a substrate 102 and one or more dies 104. The dies 104 may be any suitable die, such as a processor, a memory, a field programmable gate array (FPGA), an application-specific integrated circuit (ASIC), a storage device, a graphics processor, an accelerator, etc.

FIG. 2 shows a cross-sectional view of part of the substrate 102 and the die 104. FIG. 2 does not show all of the substrate 102 and the die 104. The substrate 102 includes layers 130A-D. Each layer 130A, 130B, 130C, 130D includes a corresponding dielectric layer 106A, 106B, 106C, 106D and one or more conductive traces 112. The conductive traces 112 may also act as pads for vias 114. Vias 114 may connect traces in one layer 106 to another layer 106.

The substrate 102 also includes layers 132A-D. Each layer 132A, 132B, 132C, 132D similarly includes a corresponding dielectric layer 110A, 110B, 110C, 110D and one or more conductive traces 118. The conductive traces 118 may also act as pads for vias 120. Vias 120 may connect traces in one layer 110 to another layer 110. The traces 112, 118 provide interconnects for, e.g., delivering power to the die 104 and providing input and output signals to and from the die 104 and/or other components connected to the substrate 102. The traces 112, 118 may route signals along and between layers 130A-D, 132A-D.

In the illustrative embodiment, the traces 118 are thinner and may be finer pitch than the traces 112. In particular, in the illustrative embodiment, the traces 118 have a thickness of 15 micrometers, and the traces 112 have a thickness of 25 micrometers. The traces 118 may have a width of 9 micrometers and a spacing of 12 micrometers between traces 118. The traces 112 may have a width of 20 micrometers and a spacing of 20 micrometers between traces 118. In some places, such as where the traces 118, 112 act as pads for vias 120, 114, the traces 112, 118 may be wider than 9 or 12 micrometers, respectively.

More generally, the traces 118 on layers 132A-D are thinner than the traces 112 on layers 130A-C. For example, the traces 118 may be 30-90% of the thickness of the traces 112. The traces 112 may have any suitable thickness, such as 15-100 micrometers. The traces 118 may also have any suitable thickness, such as 10-90 micrometers. In the illustrative embodiment, the traces 118 are copper. In other embodiments, the traces 118 (and other components described as copper herein) may be made of another metal or conductive material.

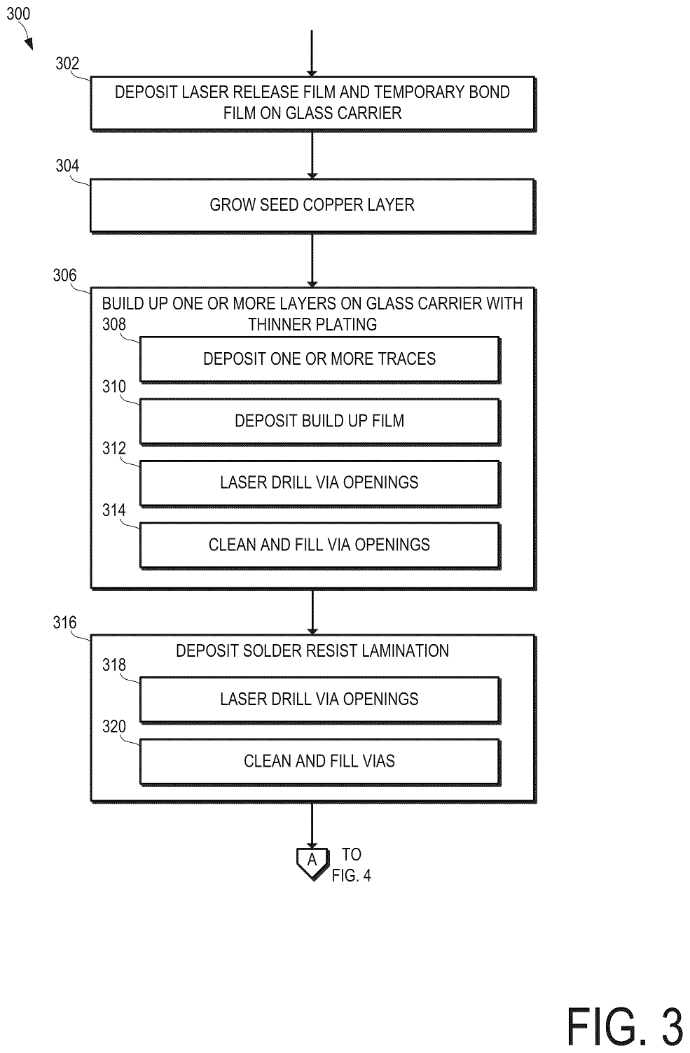

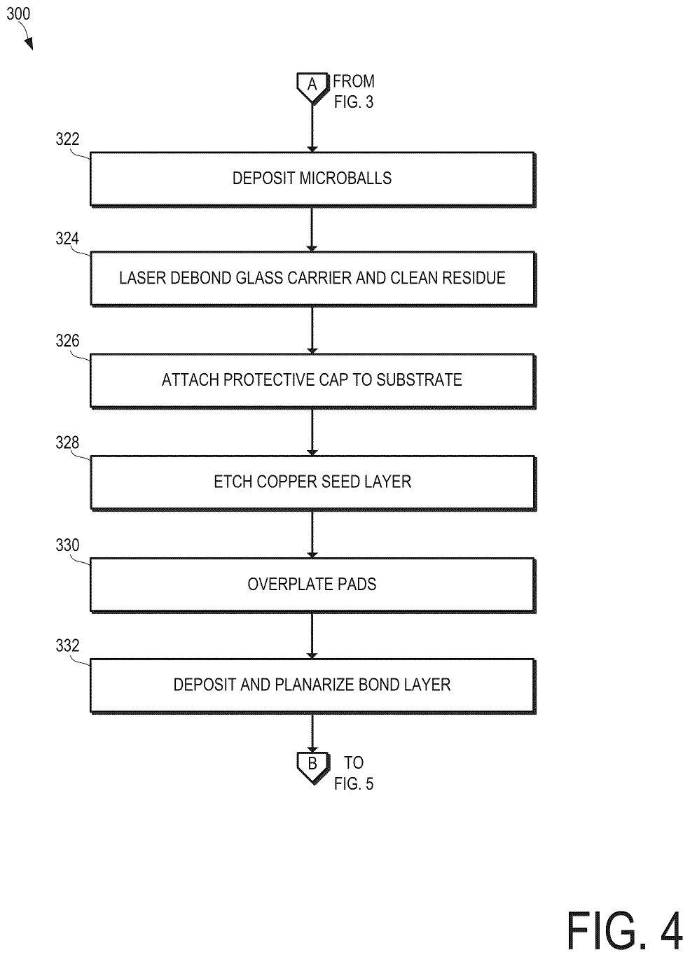

In the illustrative embodiment, the layers 130A-D are joined with the layers 132A-D by a hybrid bond 108. The hybrid bond 108 includes one or more metal-metal fusion (or direct) bonds 124, one or more metal-dielectric bonds 126, and one or more dielectric bonds 128. In the illustrative embodiment, the bonds 126, 128 with a dielectric include benzocyclobutene (BCB). In other embodiments, the bonds 126, 128 with a dielectric may include silicon oxide or silicon nitride. The formation of the hybrid bond 108 is described in more detail below in regard to the method 300 described in FIGS. 3-7.

In the illustrative embodiment, the dielectric layers 110D, 106D may be solder resist lamination. The dielectric layers 106A-C, 110A-C may be any suitable dielectric, such as Ajinomoto build-up film (ABF). The layers 130A-D, 132A-D may be any suitable thickness, such as 10-100 micrometers. In some embodiments, the layers 132A-D may be thinner than layers 130A-D, such as 40-90% of the thickness of the layers 130A-D. The vias/pads 134 may be embodied as a Cu—Ni—Sn alloy with a microball 122 of solder on top of it. The vias/pads 116 may be embodied as a Ni—Pd—Au alloy. The substrate 102 may include any suitable number of layers 130, 132, such as 1-6 layers. The number of layers 130 may be different from the number of layers 132.

It should be appreciated that the substrate 102 does include a substrate core. As described in more detail below, parts of the substrate are built up on glass carriers and combined using a hybrid bond. The lack of a substrate core can reduce the overall thickness of the substrate 102.

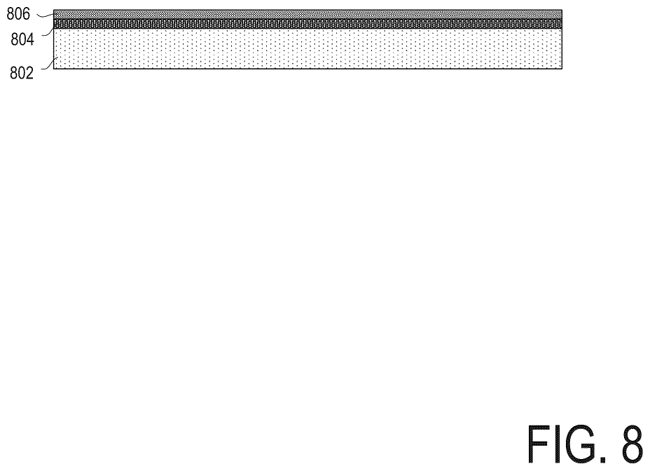

Referring now to FIG. 3, in one embodiment, a flowchart for a method 300 for creating a substrate 102 for an integrated circuit component 100 is shown. The method 300 may be executed by a technician and/or by one or more automated machines. In some embodiments, one or more machines may be programmed to do some or all of the steps of the method 300. Such a machine may include, e.g., a memory, a processor, data storage, etc. The memory and/or data storage may store instructions that, when executed by the machine, causes the machine to perform some or all of the steps of the method 300. The method 300 may use any suitable set of techniques that are used in semiconductor processing or packaging, such as electroplating, electroless plating, laser drilling, chemical vapor deposition, atomic layer deposition, physical vapor deposition, molecular beam epitaxy, pulsed laser deposition, layer transfer, photolithography, ion implantation, dry etching, wet etching, plasma etching, reactive ion etching, ion-assisted chemical vapor etching, thermal treatments, etc. FIGS. 8-29 show various stages of the method 300 from the same perspective as FIG. 2.

The method 300 begins in block 302, in which a laser release film 804 and a temporary bond film 806 are placed on a carrier substrate 802, as shown in FIG. 8. In the illustrative embodiment, the carrier substrate 802 is glass. In other embodiments, the carrier substrate 802 may be a different material.

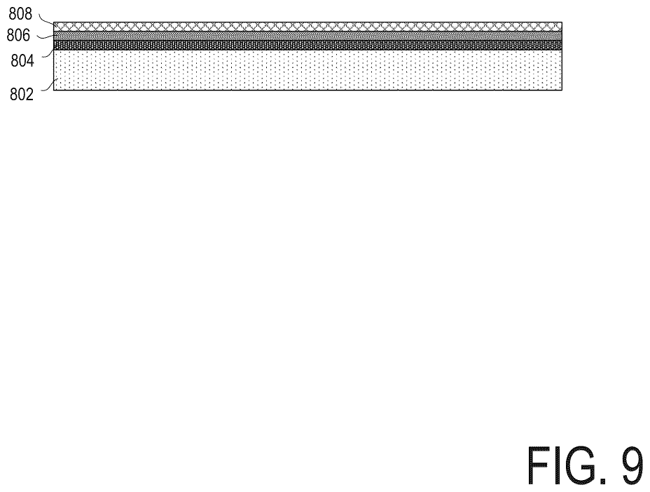

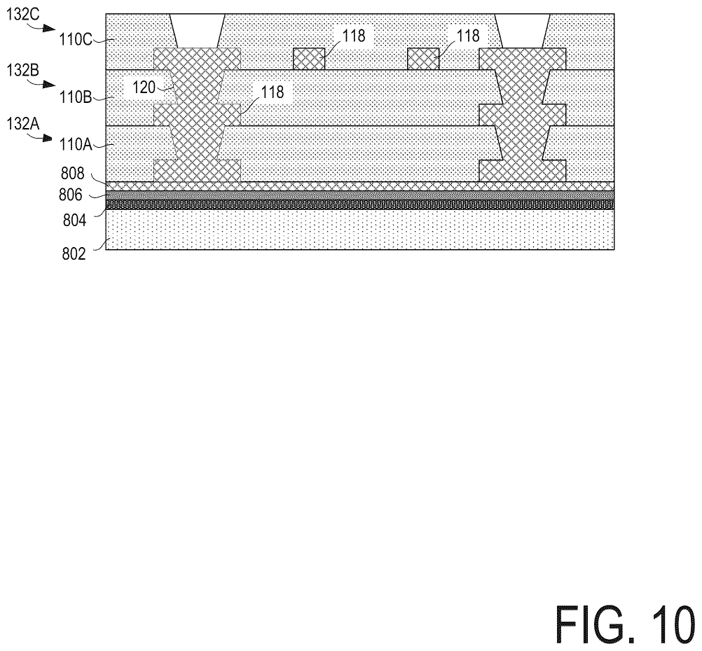

In block 304, a copper seed layer 808 is grown on the temporary bond film 806, as shown in FIG. 9. In block 306, one or more layers are built up on the glass carrier 802 using a semi-additive process with relatively thin conductive traces 118 (e.g., traces with a height of 15 micrometers). In block 308, one or more traces 118 are deposited. In block 310, a build-up film 110 is deposited. In block 312, one or more via openings are laser drilled in the build-up film 110, as shown in FIG. 10. In block 314, the via opening are desmeared and cleaned and then filled with copper. The process of building up a layer may be repeated one or more times.

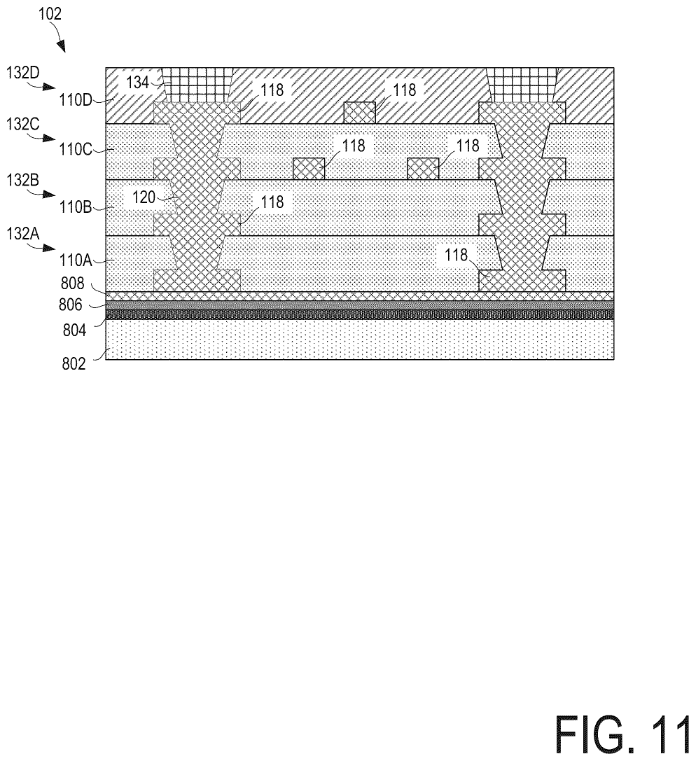

In block 316, a solder resist lamination layer 110D is deposited. In block 318, via openings are laser drilled or lithographically patterned. In block 320, the via openings are cleaned and filled with a conductive material such as a Cu—Ni—Sn alloy, as shown in FIG. 11.

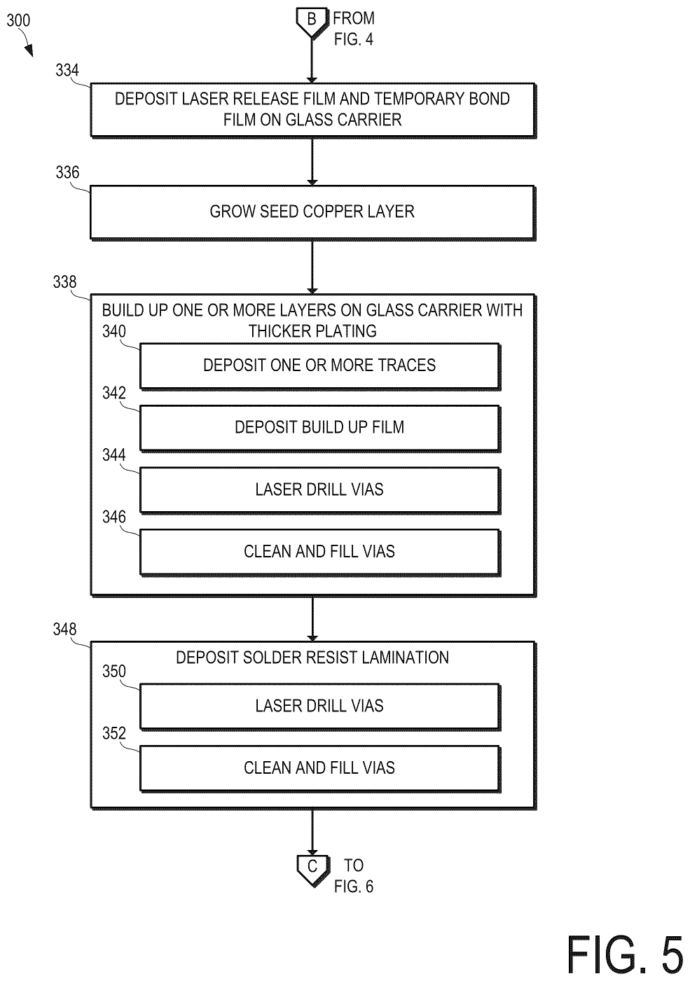

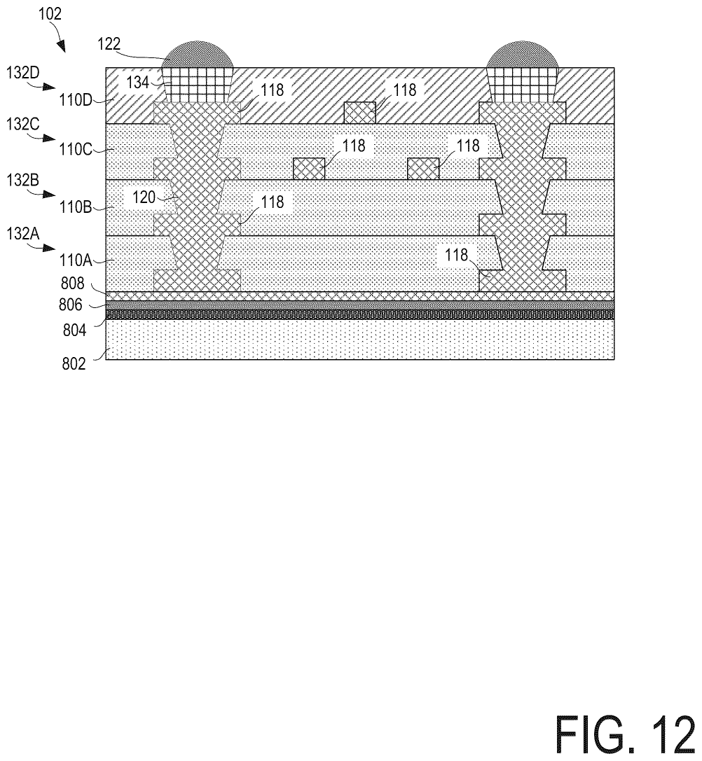

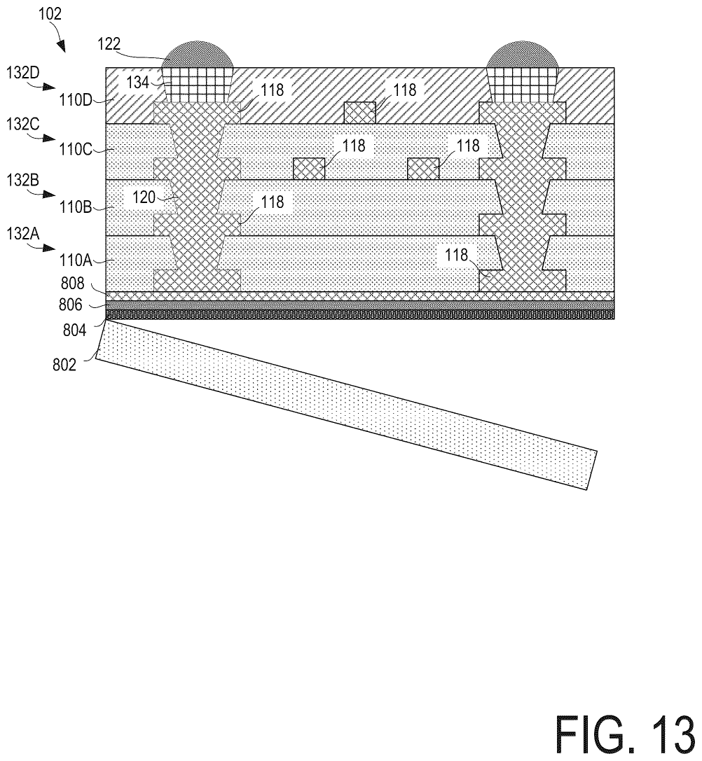

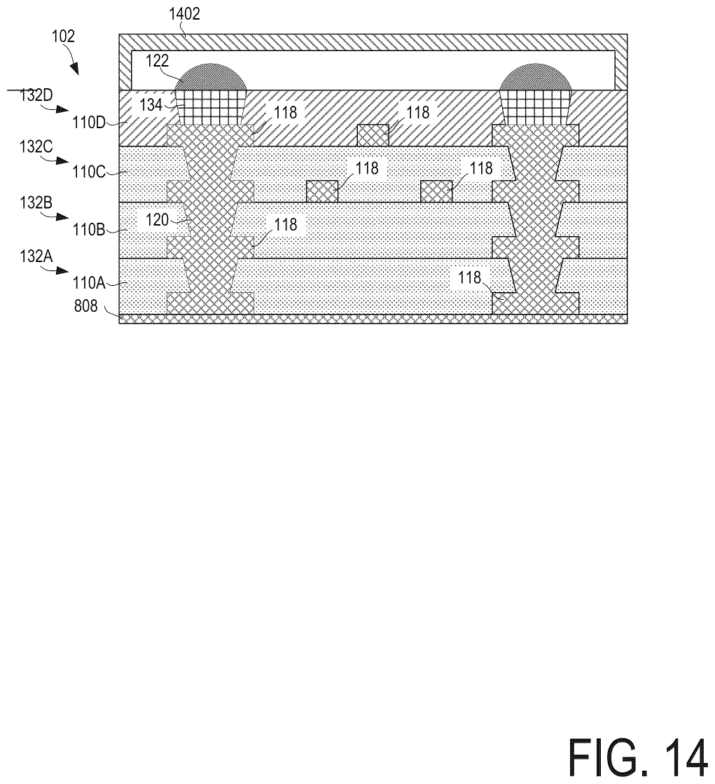

Referring now to FIG. 4, the method 300 continues to block 322, in which microballs 122 are deposited on the vias/pads 134, as shown in FIG. 12. In block 324, the glass carrier 802 is laser debonded, as shown in FIG. 13. The residue from the laser release film 804 and the temporary bond film 806 are then removed from the copper seed layer 808, as shown in FIG. 14. In block 326, a protective cap 1402 is placed over the substrate 102, protecting the microballs 122, as shown in FIG. 14.

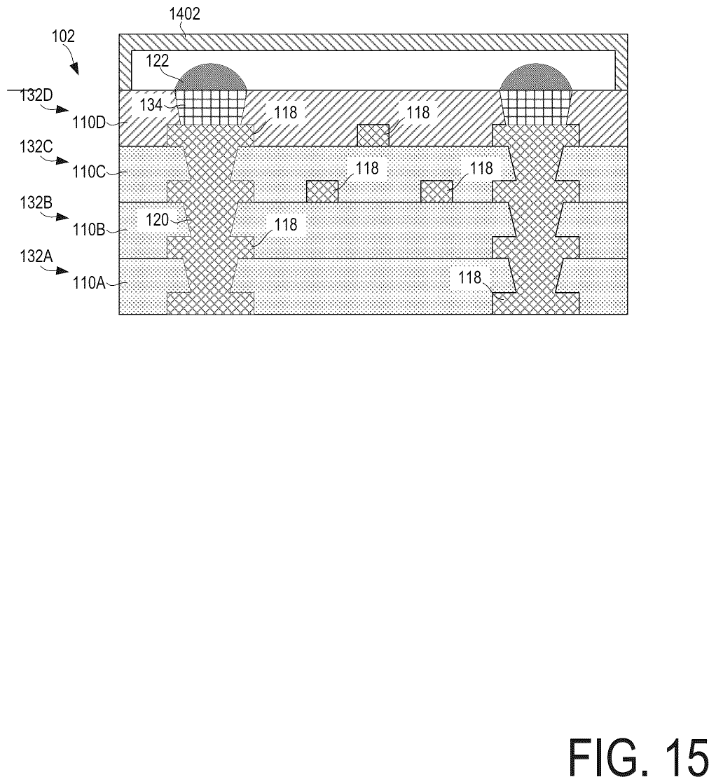

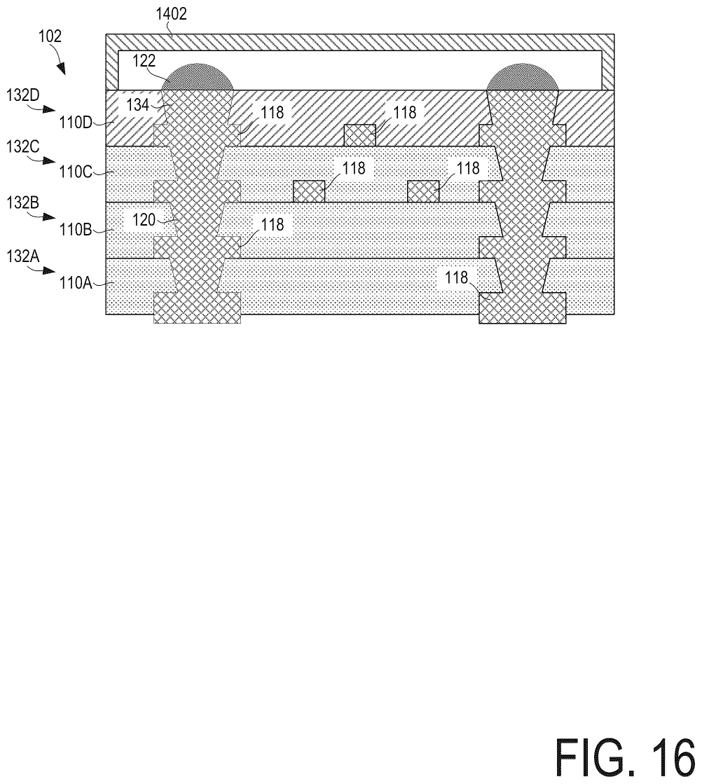

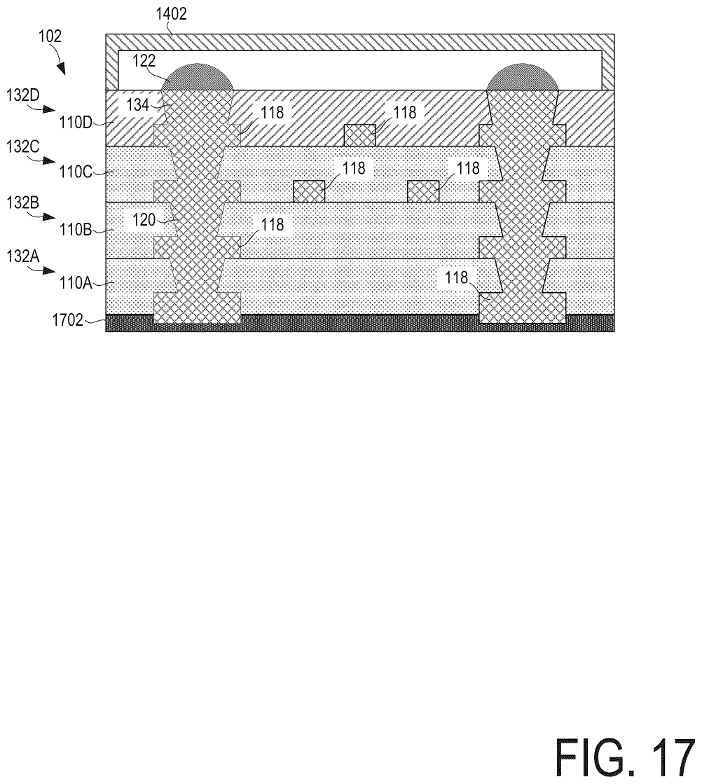

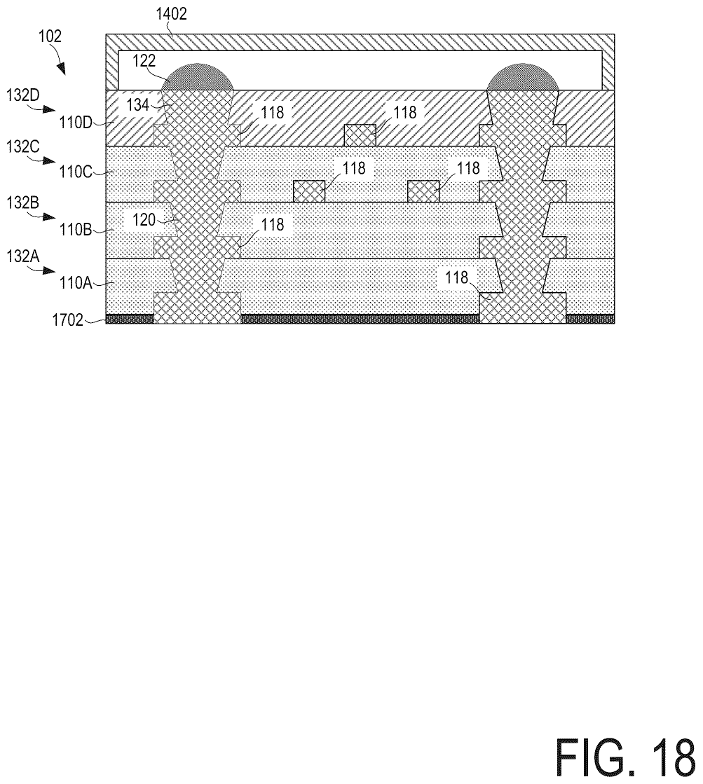

In block 328, the copper seed layer 808 is etched away, as shown in FIG. 15. In block 330, some of the traces 118 that will also act as pads are overplated, thickening those traces 118, as shown in FIG. 16. In block 332, a bond dielectric layer 1702 is deposited, as shown in FIG. 17. In the illustrative embodiment, the bond dielectric layer 1702 includes benzocyclobutene (BCB). In other embodiments, the bond dielectric layer 1702 may include silicon oxide or silicon nitride. The bond dielectric layer 1702 may then be planarized, as shown in FIG. 18.

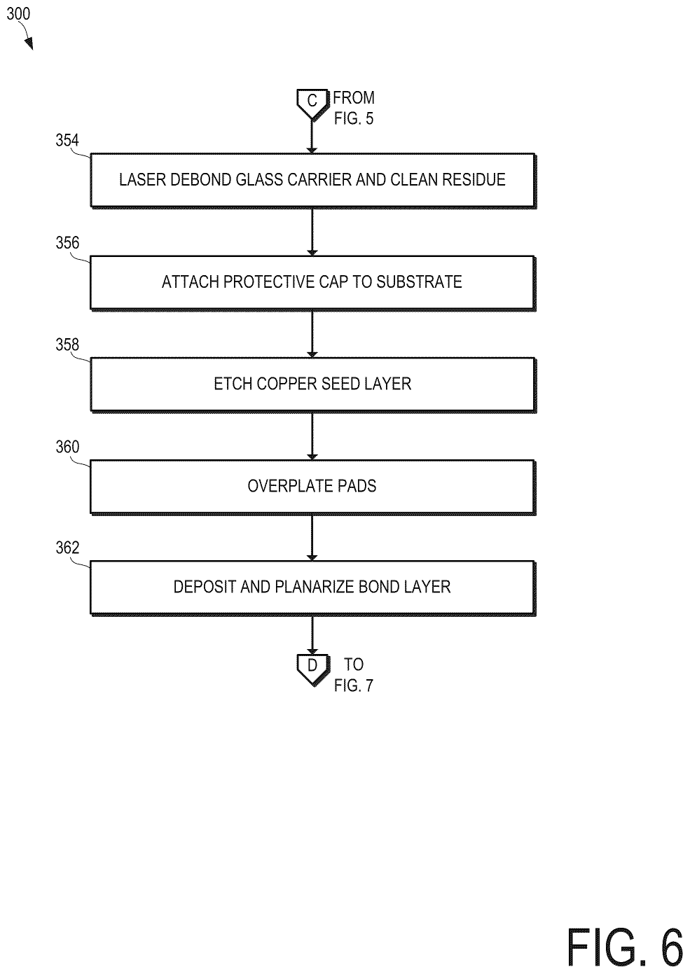

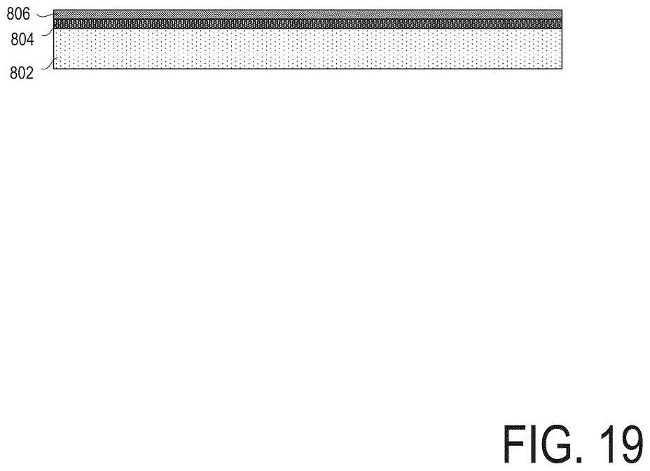

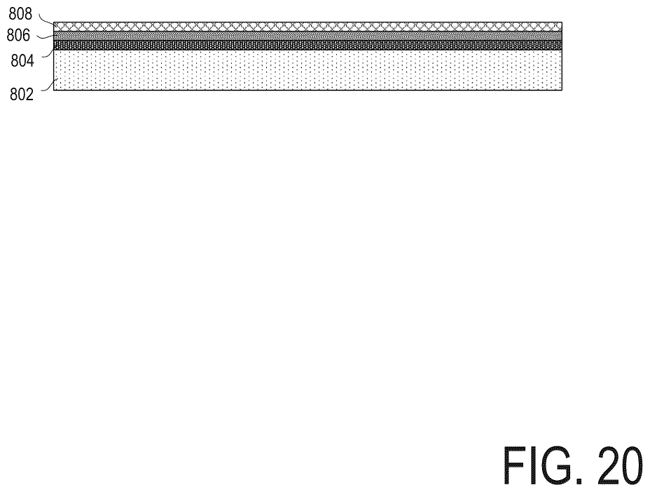

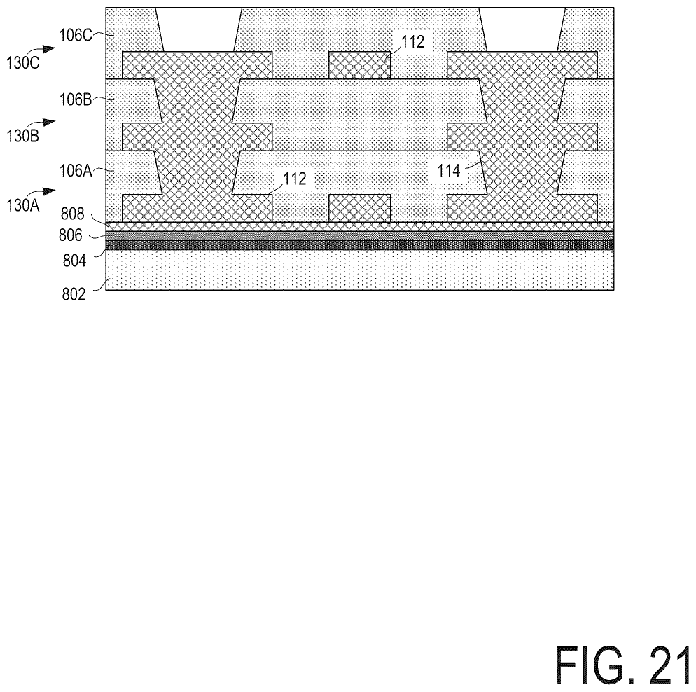

Referring now to FIG. 5, beginning in block 334, the other part of the substrate 102 is formed in a similar manner. In block 334, a laser release film 804 and a temporary bond film 806 are placed on a carrier substrate 802, as shown in FIG. 19. In block 336, a copper seed layer 808 is grown on the temporary bond film 806, as shown in FIG. 20. In block 338, one or more layers are built up on the glass carrier 802 using a semi-additive process with relatively thick conductive traces 112 (e.g., traces with a height of 25 micrometers). In block 340, one or more traces 112 are deposited. In block 342, a build-up film 106 is deposited. In block 344, one or more via openings are laser drilled in the build-up film 110, as shown in FIG. 21. In block 346, the via opening are desmeared and cleaned and then filled with copper. The process of building up a layer may be repeated one or more times.

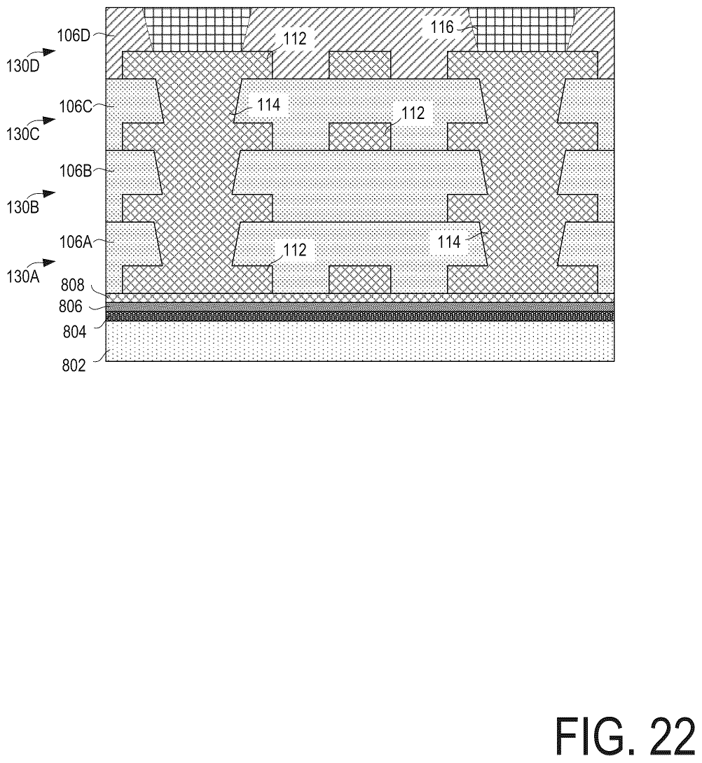

In block 348, a solder resist lamination layer 106D is deposited. In block 350, via openings are laser drilled or lithographically patterned. In block 352, the via openings are cleaned and filled with a conductive material such as a Ni—Pd—Au alloy, as shown in FIG. 22.

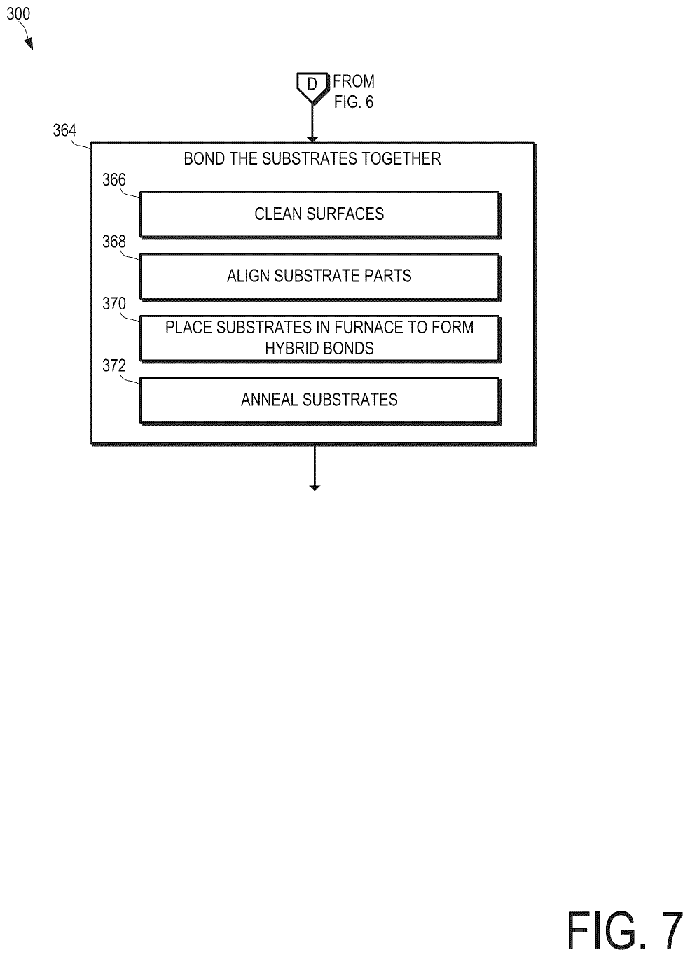

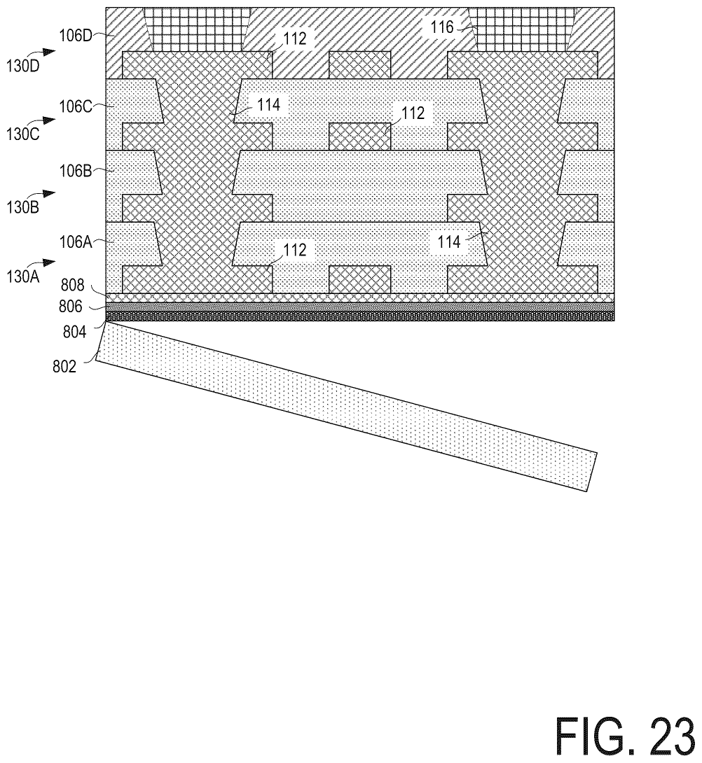

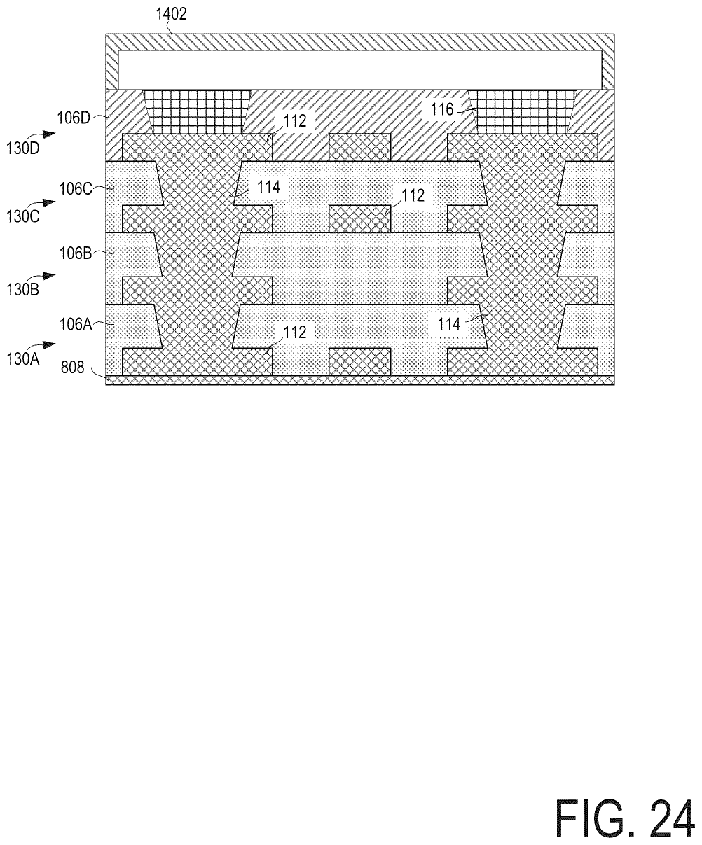

Referring now to FIG. 6, the method 600 continues to block 354, in which the glass carrier 802 is laser debonded, as shown in FIG. 23. The residue from the laser release film 804 and the temporary bond film 806 are then removed from the copper seed layer 808, as shown in FIG. 24. In block 356, a protective cap 1402 is placed over the substrate 102, protecting the vias/pads 116, as shown in FIG. 24.

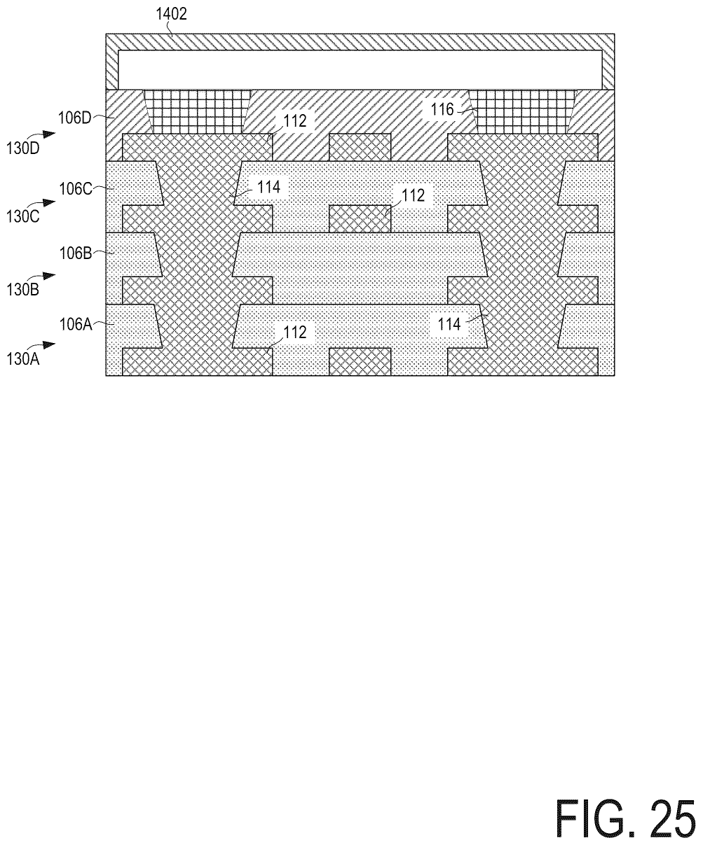

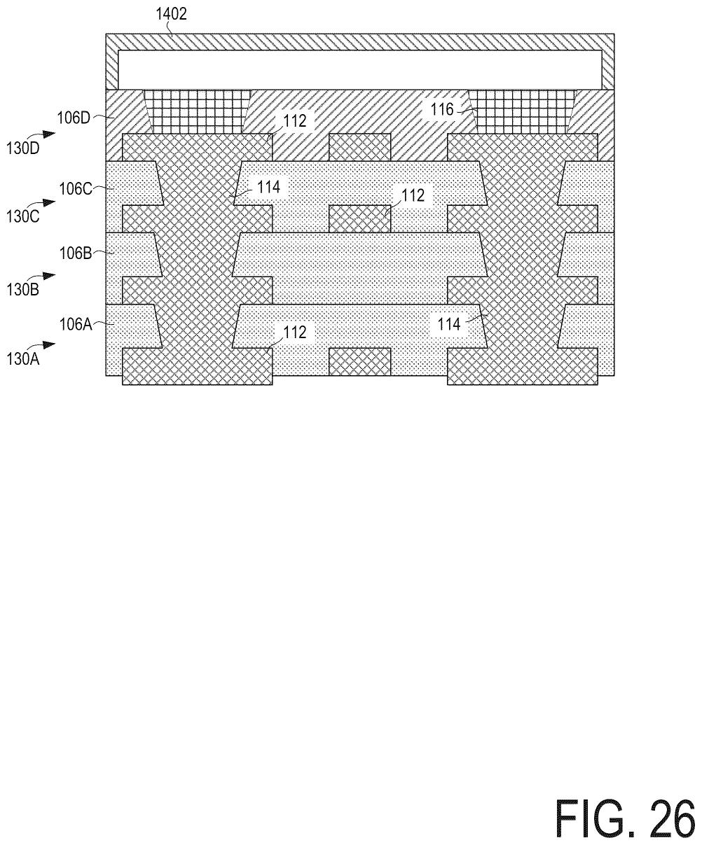

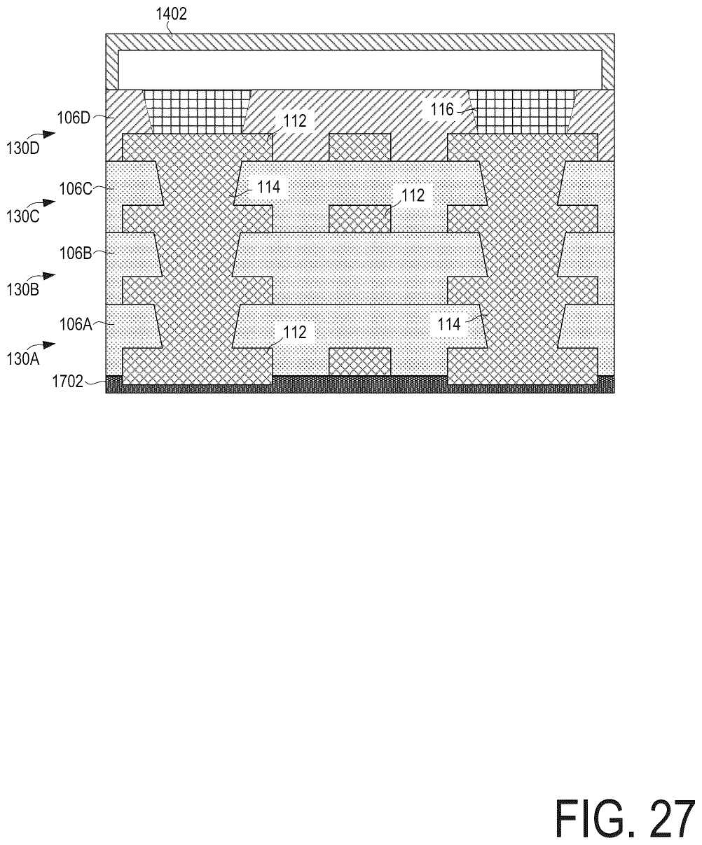

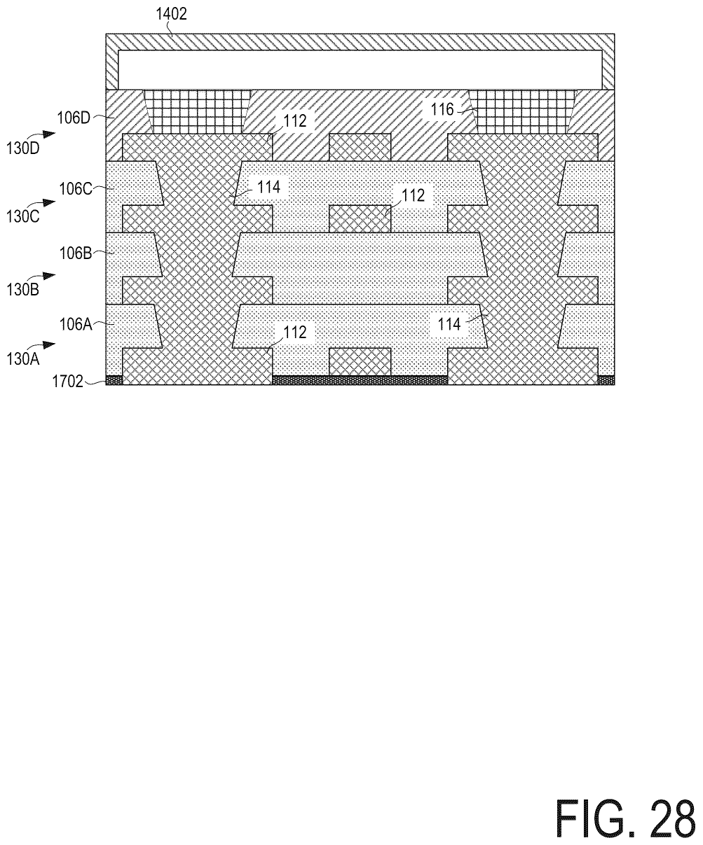

In block 358, the copper seed layer 808 is etched away, as shown in FIG. 25. In block 360, some of the traces 112 that will also act as pads are overplated, thickening those traces 112, as shown in FIG. 26. In block 362, a bond dielectric layer 1702 is deposited, as shown in FIG. 27. In the illustrative embodiment, the bond dielectric layer 1702 includes benzocyclobutene (BCB). In other embodiments, the bond dielectric layer 1702 may include silicon oxide or silicon nitride. The bond dielectric layer 1702 may then be planarized, as shown in FIG. 28.

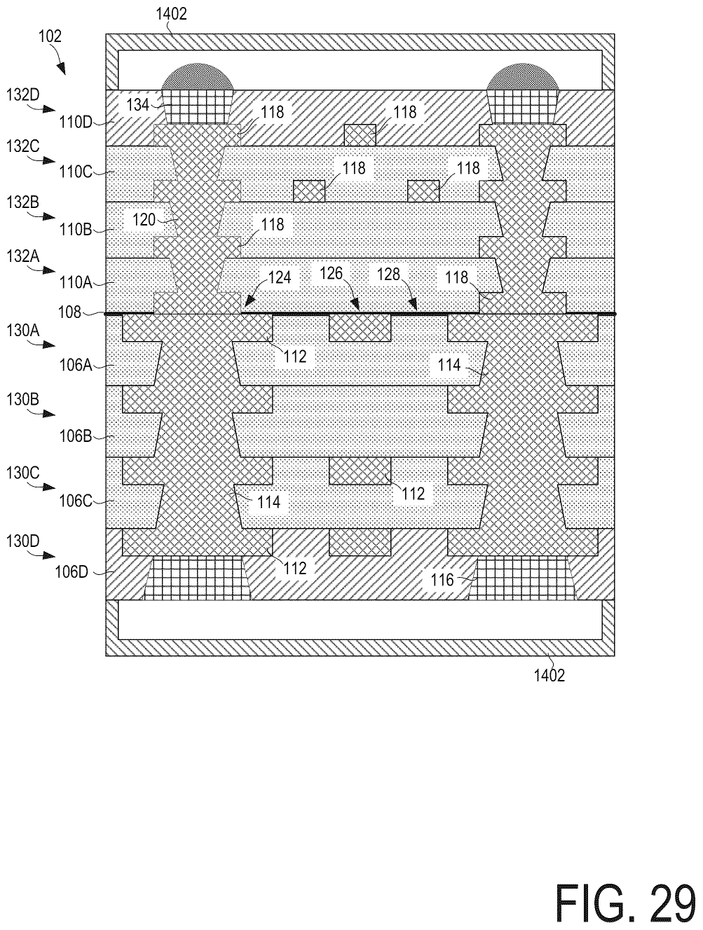

Referring now to FIG. 7, in block 364, the two parts of the substrate 102 are bonded together, as shown in FIG. 29. In block 366, the surfaces to be bonded together are cleaned and otherwise prepared for bonding. A chemical mechanical polishing (CMP) process can be carried out to control undulation and roughness to the submicron scale. A wet (chemical) or dry (plasma) process can be used to prepare the copper surfaces to be free of any oxide or foreign material.

In block 368, the substrate parts are aligned. The substrate parts may be aligned using fiducial marks on the substrate parts. To improve the overlay precision, the substrate parts can be built with design considerations and mask bias to match the overall shrinkage of the two substrate parts. The substrate parts may then be clamped together.

In block 370, the substrate parts may be placed in a vacuum furnace at a temperature of around 150° C. for 30 minutes for diffusion bonding of the copper traces 112, 118 and adhesive bonding of the copper traces 112, 118 with the dielectric bond layer 1702 as well as for dielectric bonding of the dielectric bond layer 1702. In the illustrative embodiment, the bonding of the copper traces 112, 118 is the spontaneous adhesion of hydrophilic surfaces followed by copper diffusion across the bonding interface 108. The substrate 102 can be annealed at a temperature of 200° C. for 30 minutes to remove any residual stress and promote grain growth to improve both the interfacial strength and electrical conductivity. In other embodiments, a different bonding procedure may be used, such as applying different temperatures for different amounts of times. In general, the substrate 102 may be held at one or more temperatures of, e.g., 100-300° C. for a duration of 20 minutes to three hours.

After the two substrate parts are bonded together, the protective caps 1402 may be removed from the substrate 102. The substrate 102 may be integrated with other components such as a die 104, as shown in FIG. 1.

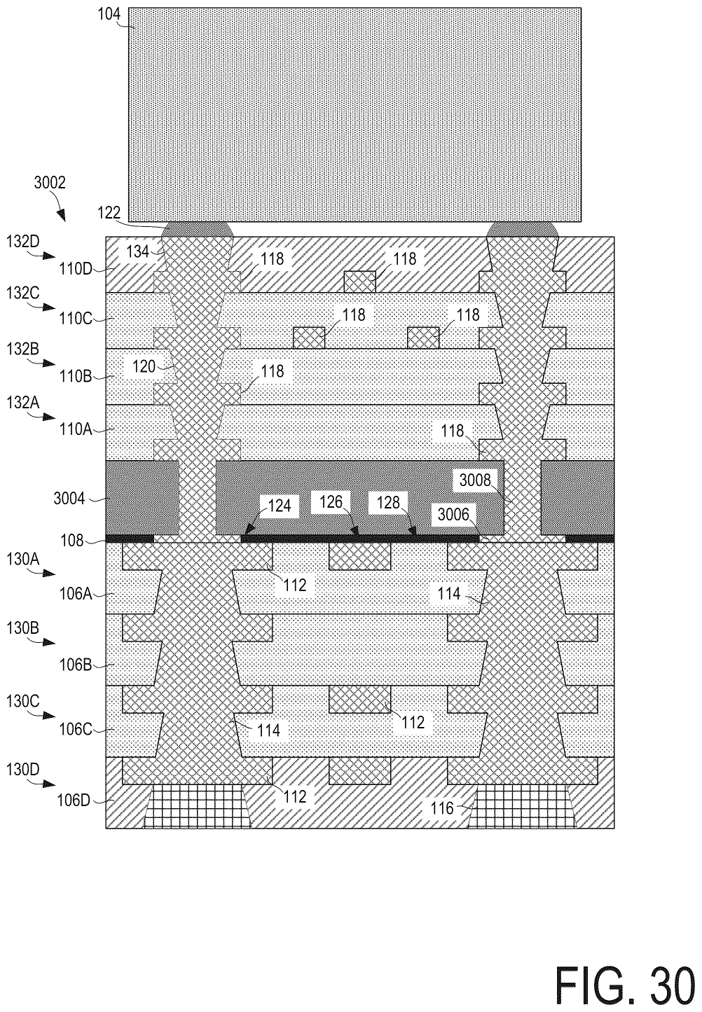

Referring now to FIG. 30, in one embodiment, a substrate 3002 with a substrate core 3004 is shown. The substrate 3002 may be similar to the one or more substrate 102 described above, and similar components may have similar or the same labels. A description of the aspects of the substrate 3002 that are similar or the same as the substrate 102 will not be repeated in the interest of clarity.

The substrate 3002 includes a substrate core 3004. As described in more detail below, part of the substrate 1002 is built up on the substrate core 3004. The substrate core 3004 may provide more support and/or rigidity to the substrate 3002. The substrate core 3004 may be any suitable substrate core, such as resin with glass fiber, FR-4, CEM-1, etc. One or more vias 3008 pass through the substrate core 3004. The vias 3008 may be filled with copper or other metal. Traces or pads 3006 may be present on one side of the substrate core 3004. The substrate core 3004 is joined with another substrate part through a hybrid bond 108 in a similar manner as the substrate 102 described above.

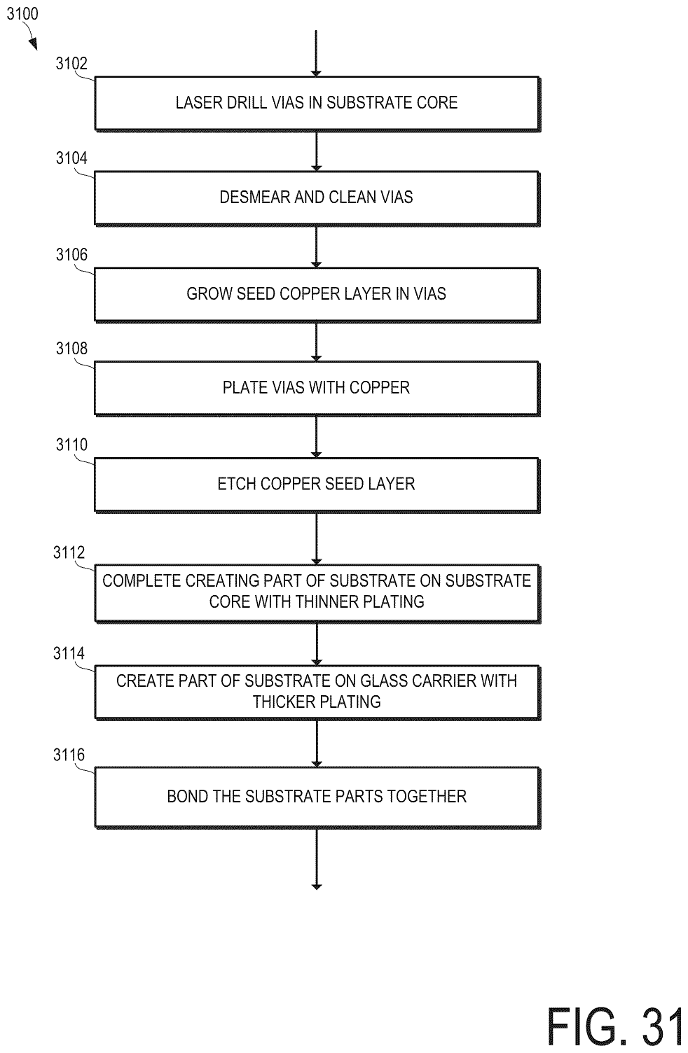

Referring now to FIG. 31, in one embodiment, a flowchart for a method 3100 for creating a substrate 3002 for an integrated circuit component 100 is shown. The method 3100 may be executed in a similar manner and using similar techniques as the method 300 above. In some cases, similar materials such as laminate layers and bond material may be used in the method 3100 in a similar manner as the method 300. Some of the details of the techniques, materials, etc., of the method 300 will not be repeated in the interest of clarity.

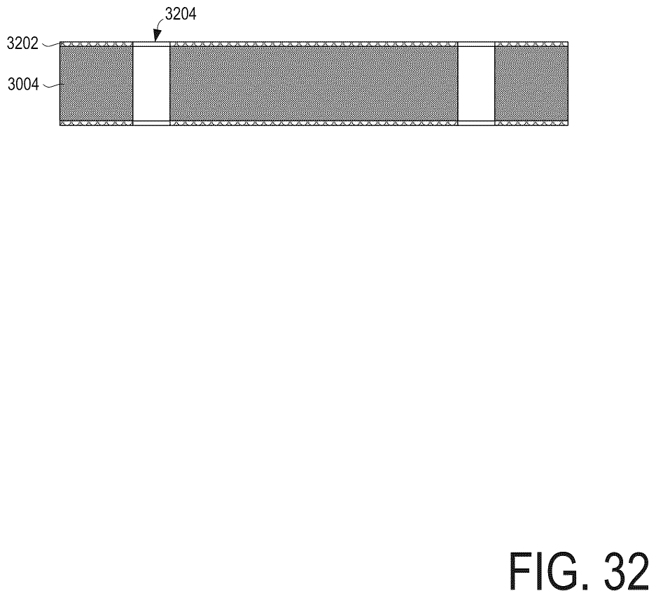

The method 3100 begins in block 3102, in which one or more vias 3204 are laser drilled in a substrate core 3004, as shown in FIG. 32. In the illustrative embodiment, the substrate core 3004 is a copper-clad laminate layer 3004 with a copper cladding 3202 on the top and bottom surfaces of the laminate layer. In block 3104, the vias 3204 are desmeared and cleaned.

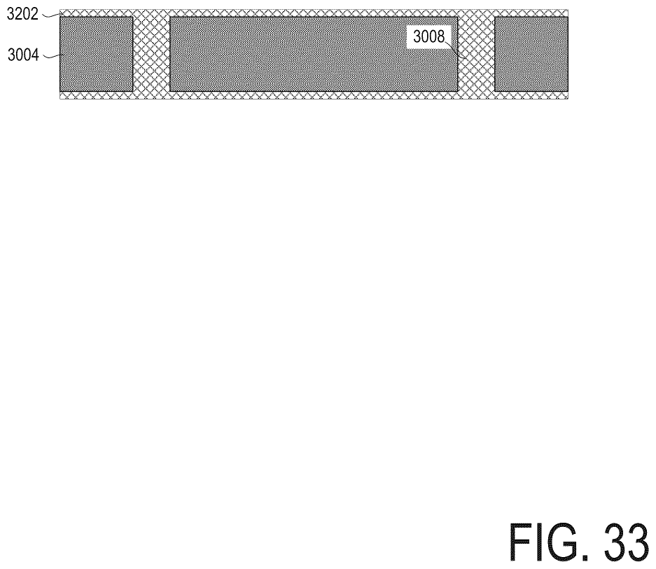

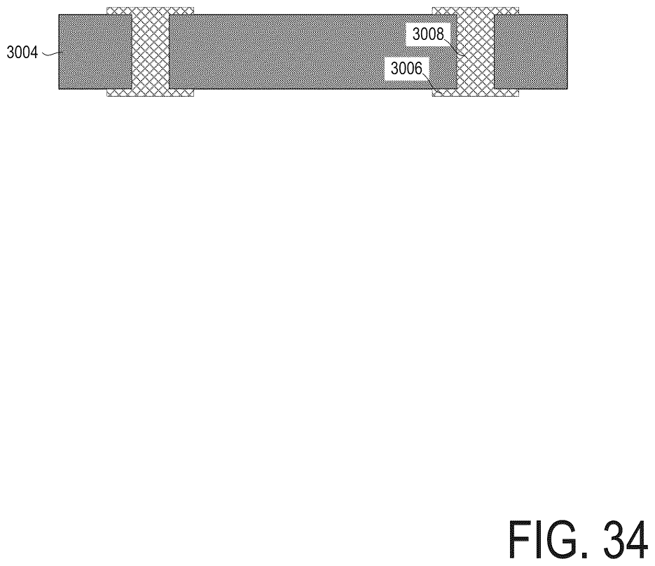

In block 3106, a copper seed layer is grown in the vias, such as by using electroless plating. In block 3108, the vias are plated with copper, such as by using electrolytic plating, as shown in FIG. 33. In block 3110, part of the copper seed layer of the substrate core 3004 is etched away, leaving traces 3006, as shown in FIG. 34.

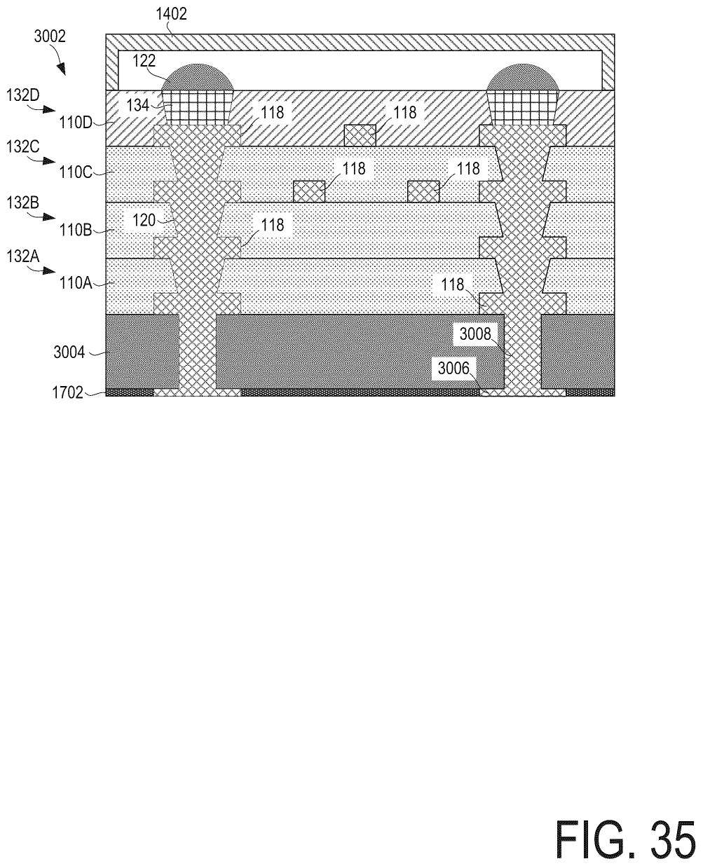

In block 3112, the rest of the part of the substrate is created on the substrate core 3004, as shown in FIG. 35, as for the part of the substrate formed in blocks 306-332 of the method 300. As discussed above in more detail, one or more layers are built up on the substrate core 3004 using a semi-additive process with relatively thin conductive traces 118 (e.g., traces with a height of 15 micrometers). A solder resist lamination layer 110D may be deposited as the last layer, with pads/vias with a conductive material such as a Cu—Ni—Sn alloy. Microballs 122 may be deposited on the vias/pads 134. A protective cap 1402 is placed over the substrate 102, protecting the microballs 122. A bond dielectric layer 1702 is deposited and planarized.

In block 3114, another part of the substrate is formed on a glass carrier, as discussed above in regard to blocks 334-362 in the method 300, a description of which will not be repeated in the interest of clarity.

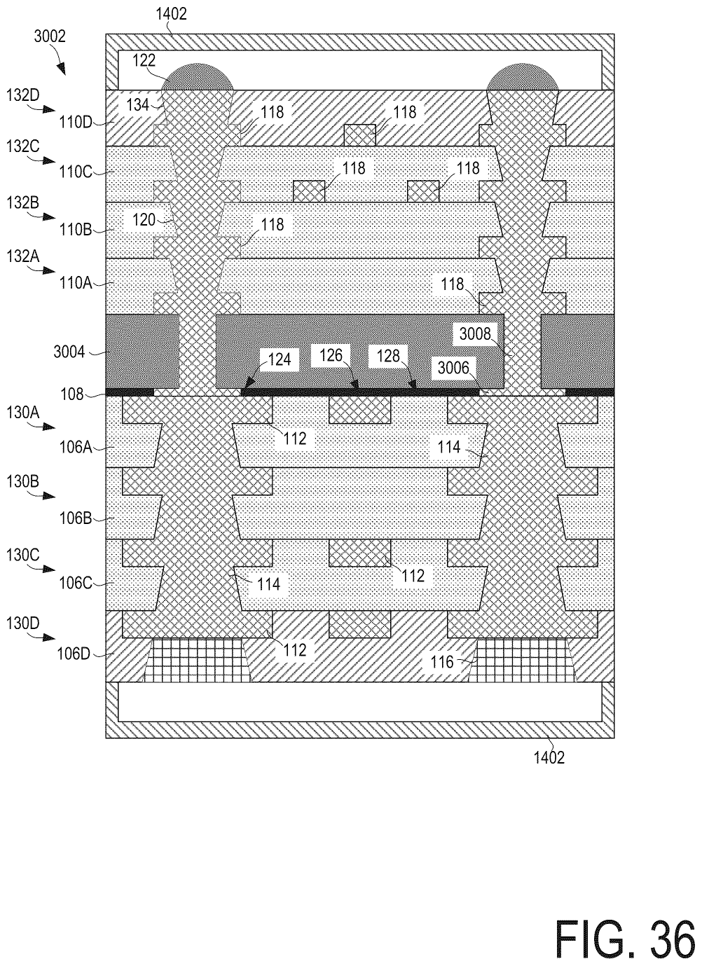

In block 3116, the parts of the substrate are bonded together, as shown in FIG. 36. The surfaces to be bonded together are cleaned and otherwise prepared for bonding. A chemical mechanical polishing (CMP) process can be carried out to control undulation and roughness to the submicron scale. A wet (chemical) or dry (plasma) process can be used to prepare the copper surfaces to be free of any oxide or foreign material. The substrate parts are aligned using fiducial marks on the substrate parts and may then be clamped together. The substrate parts may be placed in a vacuum furnace at a temperature of around 150° C. for 30 minutes to establish the hybrid bond. The substrate 102 can be annealed at a temperature of 200° C. for 30 minutes to remove any residual stress and promote grain growth to improve both the interfacial strength and electrical conductivity.

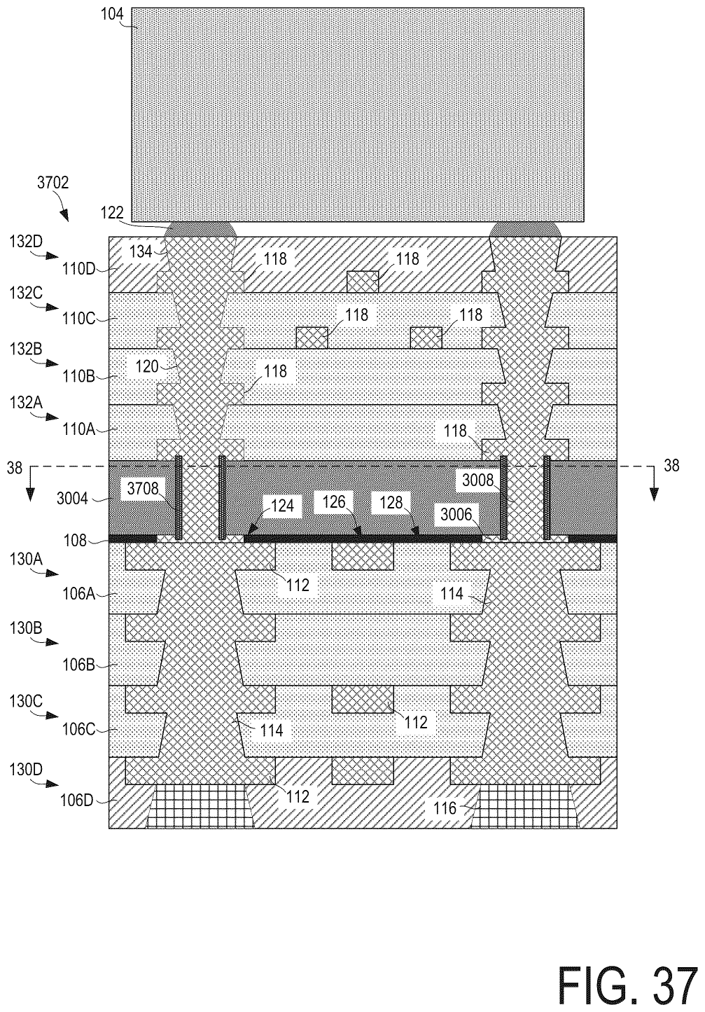

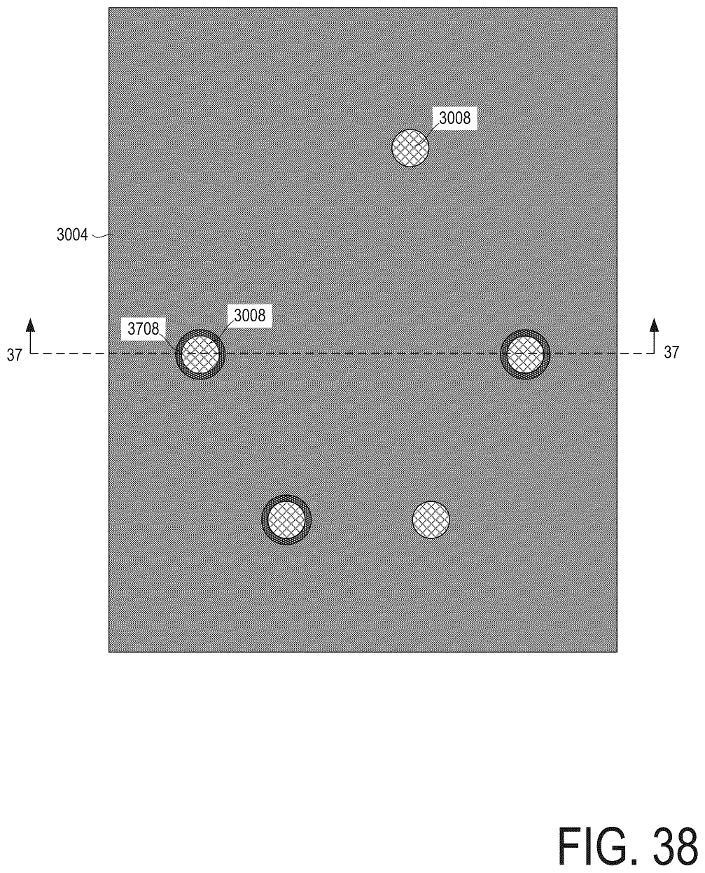

Referring now to FIG. 37, in one embodiment, a substrate 3702 with a substrate core 3004 with a magnetic lining 3708 around one or more vias 3008 through the substrate core 3004 is shown. The magnetic lining 3708 increases the inductance for vias 3008 through the substrate core 3004. The vias 3008 with a magnetic lining 3708 may be used for, e.g., power delivery, voltage regulation, etc. The increased inductance of the vias 3008 can increase the voltage stability and/or current stability of the vias 3008. As shown in FIG. 38, the magnetic lining 3708 may surround the vias 3008 as they pass through the substrate core 3004. The magnetic lining 3708 may have any suitable thickness, such as a diameter of 1-50 micrometers larger than the diameter of the vias 3008.

The magnetic lining 3708 may include any suitable magnetic material. In an illustrative embodiment, the magnetic lining 3708 may be embodied as iron-cobalt and/or iron-nickel ferromagnetic alloy powders or nanoflakes mixed with an adjustable amount of carrier polymers such as polyimide or an epoxy resin and an organic solvent. The magnetic lining 3708 may have a narrow hysteresis loop with near-zero coercive magnetic field, which may be desirable for inductor applications. The iron-cobalt and/or iron-nickel particles may have a relative permeability on the order of 1,000, with the magnetic lining 3708 having a relative permeability on the order of 100. More generally, the magnetic lining 3708 may have a relative permeability of, e.g., 10-1,000.

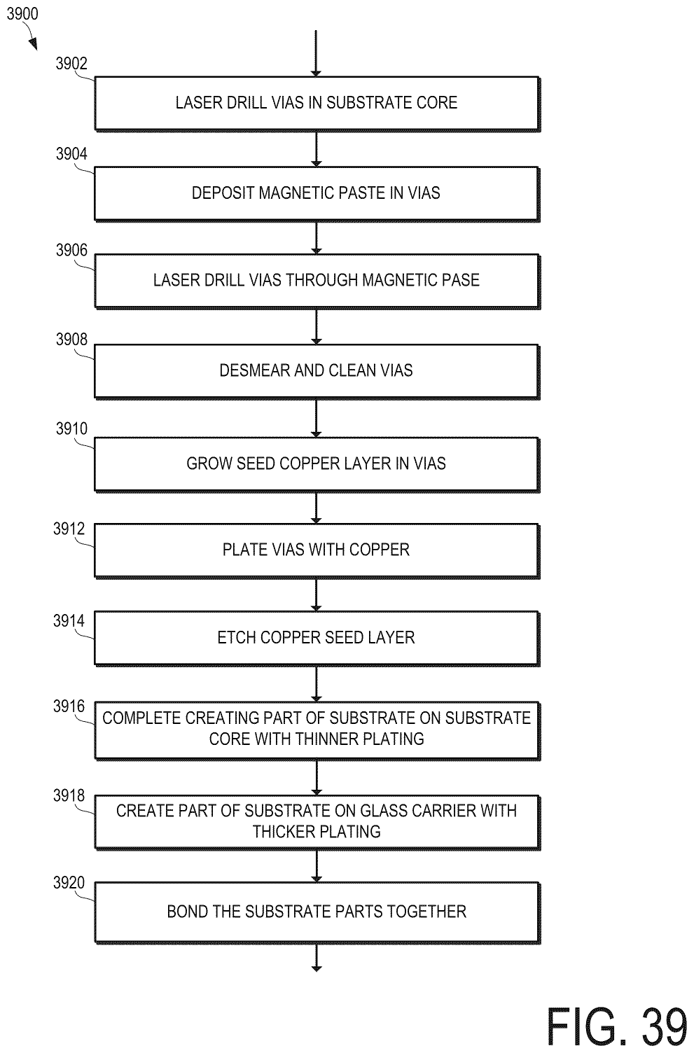

Referring now to FIG. 39, in one embodiment, a flowchart for a method 3900 for creating a substrate 3702 for an integrated circuit component 100 is shown. The method 3900 may be executed in a similar manner and using similar techniques as the method 300 above. In some cases, similar materials such as laminate layers and bond material may be used in the method 3900 in a similar manner as the method 300. Some of the details of the techniques, materials, etc., of the method 300 will not be repeated in the interest of clarity.

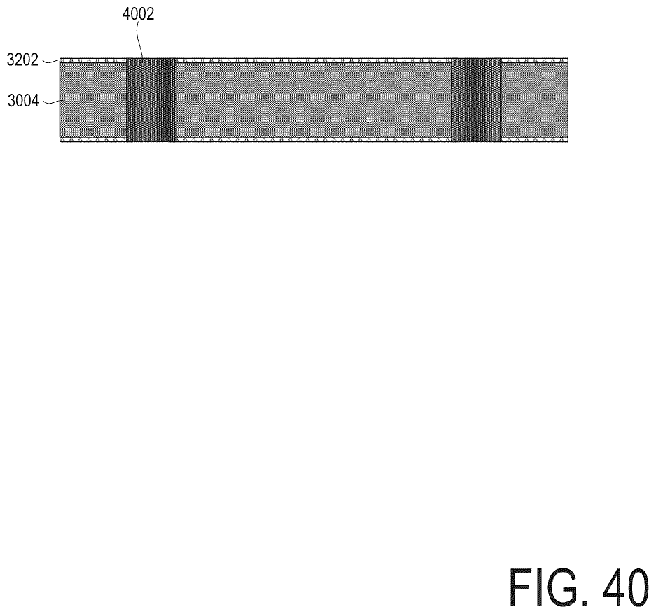

The method 3900 begins in block 3902, in which one or more vias are laser drilled in a substrate core 3004. In block 3904, a magnetic paste 4002 may be deposited and cured, as shown in FIG. 40. A precursor material such as CoNiFe, NiFeMo, and/or NiFe may be used to form the magnetic paste 4002. The precursor material is mixed using an adjustable amount of carrier polymers such as epoxy resins and an organic solvent to create a thick and viscous slurry for plugging inside the vias and cavity using a stencil-based printer or inkjet printer.

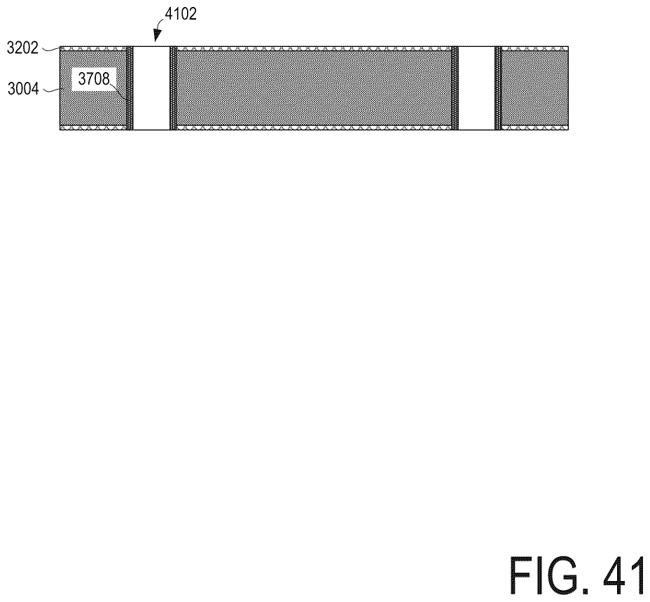

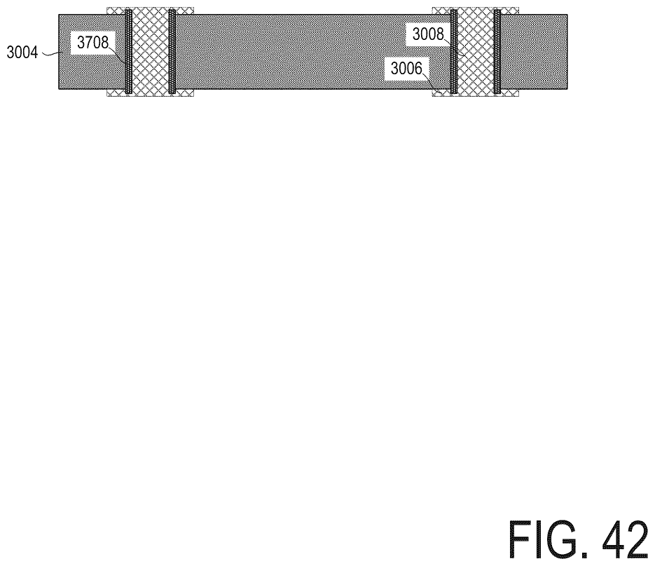

In block 3906, vias 4102 are laser drilled through the magnetic paste 4002, leaving magnetic linings 3708 behind, as shown in FIG. 41. In block 3908, the vias are desmeared and cleaned. In block 3910, a copper seed layer is grown on the magnetic linings 3708, such as by using electroless plating. In block 3912, the vias are plated with copper, such as by using electrolytic plating. In block 3914, part of the copper seed layer of the substrate core 3004 is etched away, leaving traces 3006 and vias 3008 surrounded by the magnetic linings 3708, as shown in FIG. 42.

In block 3916, the rest of the part of the substrate is created on the substrate core 3004, as shown in FIG. 43, as for the part of the substrate formed in blocks 306-332 of the method 300. As discussed above in more detail, one or more layers are built up on the substrate core 3004 using a semi-additive process with relatively thin conductive traces 118 (e.g., traces with a height of 15 micrometers). A solder resist lamination layer 110D may be deposited as the last layer, with pads/vias with a conductive material such as a Cu—Ni—Sn alloy. Microballs 122 may be deposited on the vias/pads 134. A protective cap 1402 is placed over the substrate 102, protecting the microballs 122. A bond dielectric layer 1702 is deposited and planarized.

In block 3918, another part of the substrate is formed on a glass carrier, as discussed above in regard to blocks 334-362 in the method 300, a description of which will not be repeated in the interest of clarity.

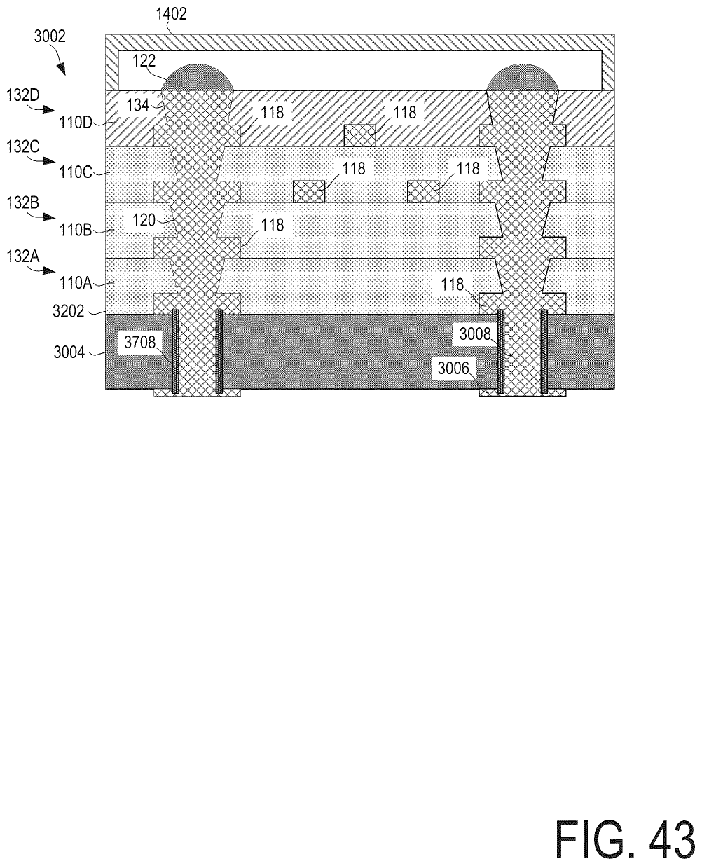

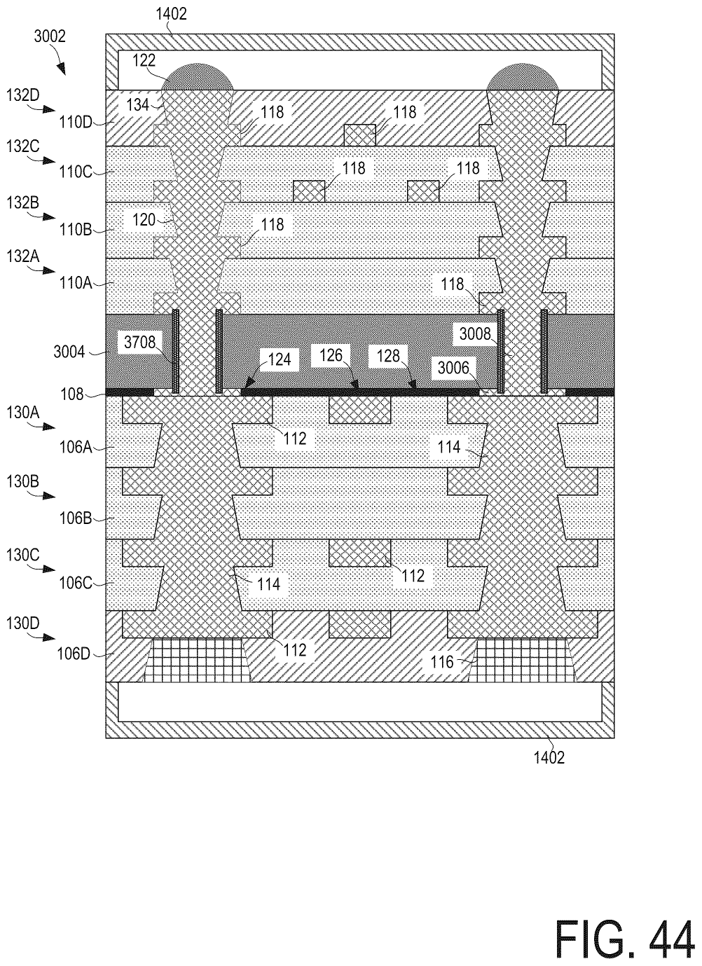

In block 3920, the parts of the substrate are bonded together, as shown in FIG. 44. The surfaces to be bonded together are cleaned and otherwise prepared for bonding. A chemical mechanical polishing (CMP) process can be carried out to control undulation and roughness to the submicron scale. A wet (chemical) or dry (plasma) process can be used to prepare the copper surfaces to be free of any oxide or foreign material. The substrate parts are aligned using fiducial marks on the substrate parts and may then be clamped together. The substrate parts may be placed in a vacuum furnace at a temperature of around 150° C. for 30 minutes to establish the hybrid bond. The substrate 102 can be annealed at a temperature of 200° C. for 30 minutes to remove any residual stress and promote grain growth to improve both the interfacial strength and electrical conductivity.

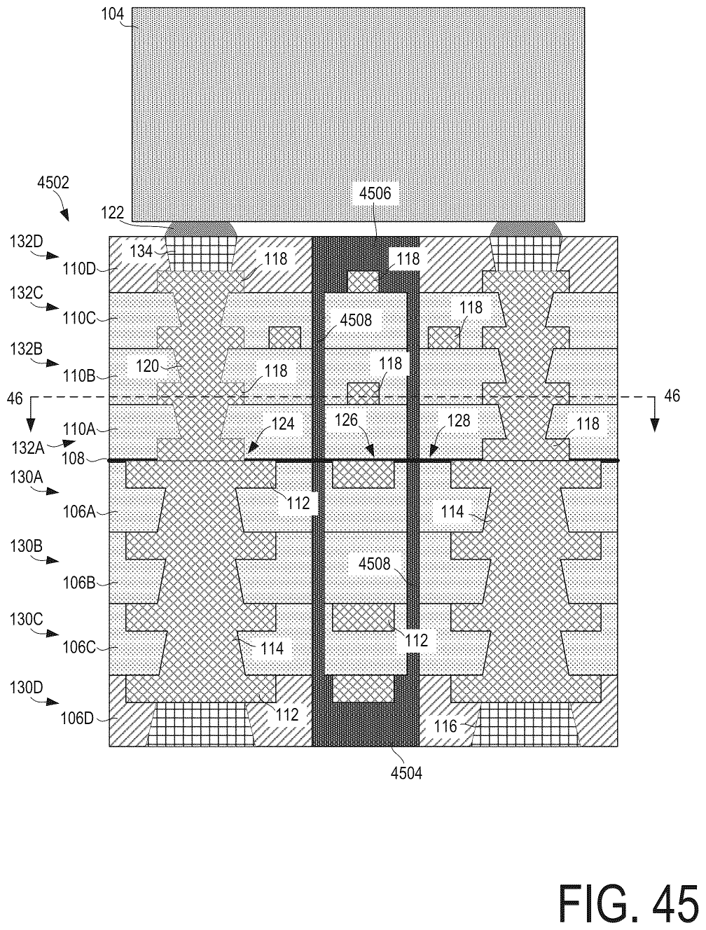

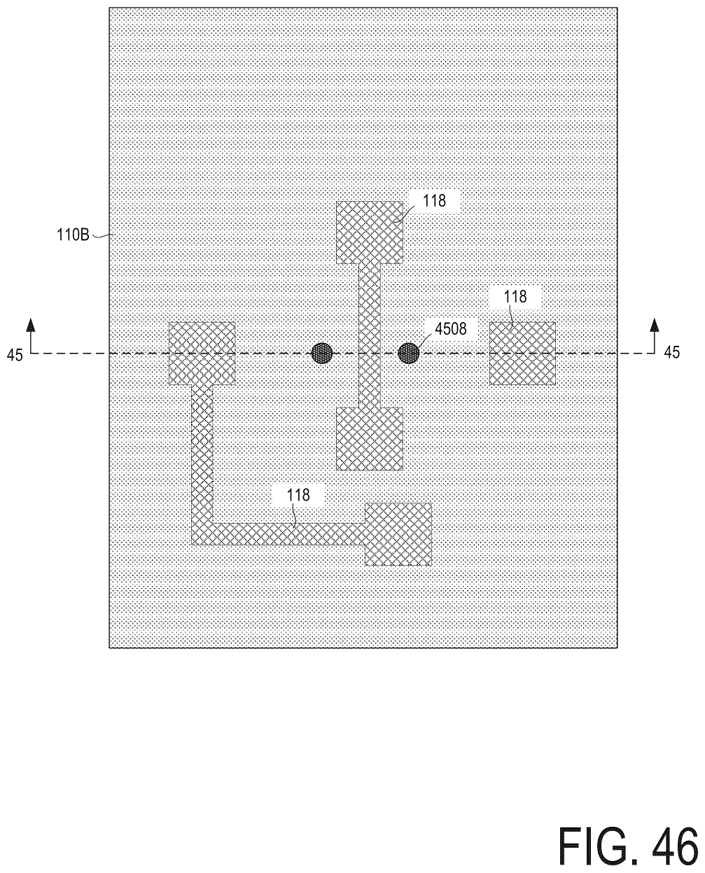

Referring now to FIG. 45, in one embodiment, a substrate 4502 with one or more embedded magnetic cores 4508 is shown. The substrate 4502 includes a magnetic cap 4506 in a top layer 110D and a magnetic cap 4504 in a bottom layer 106D. A cross-section of layer 110B showing the magnetic core 4508 is shown in FIG. 46. The magnetic cores 4508 and the magnetic caps 4506, 4504 increase the inductance of any traces 118, 112 surrounded by or nearby the magnetic cores 4508 and the magnetic caps 4506, 4504. Similar to the magnetic lining 3708, the magnetic cores 4508 and the magnetic caps 4506, 4504 increases the inductance for traces 118, 112, which may improve performance for, e.g., power delivery, voltage regulation, etc. The magnetic cores 4508 and the magnetic caps 4506, 4504 may be the same or a similar material as the magnetic linings 3708.

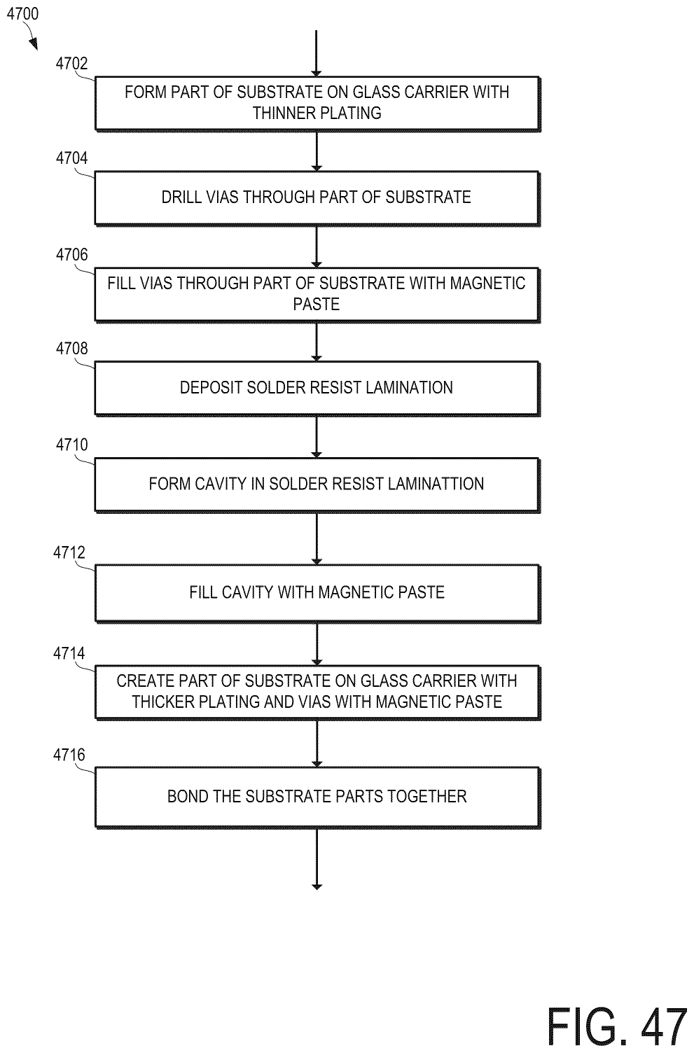

Referring now to FIG. 47, in one embodiment, a flowchart for a method 4700 for creating a substrate 4502 for an integrated circuit component 100 is shown. The method 4700 may be executed in a similar manner and using similar techniques as the method 300 above. In some cases, similar materials such as laminate layers and bond material may be used in the method 4700 in a similar manner as the method 300. Some of the details of the techniques, materials, etc., of the method 300 will not be repeated in the interest of clarity.

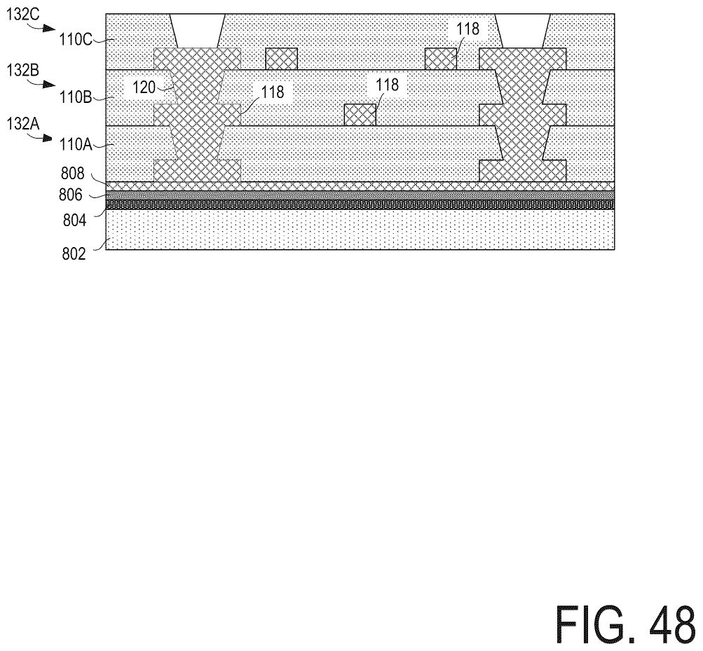

The method 4700 begins in block 4702, in which part of the substrate is created on glass carrier 802, as shown in FIG. 48. The part of the substrate may be formed in a similar manner as part of the substrate formed in blocks 302-314 of the method 300. As discussed above in more detail, one or more layers are built up on the substrate core 3004 using a semi-additive process with relatively thin conductive traces 118 (e.g., traces with a height of 15 micrometers).

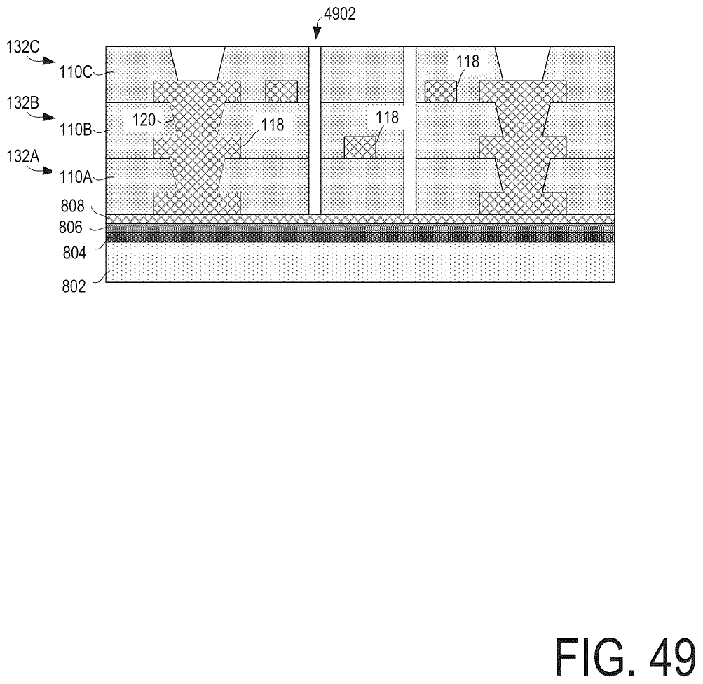

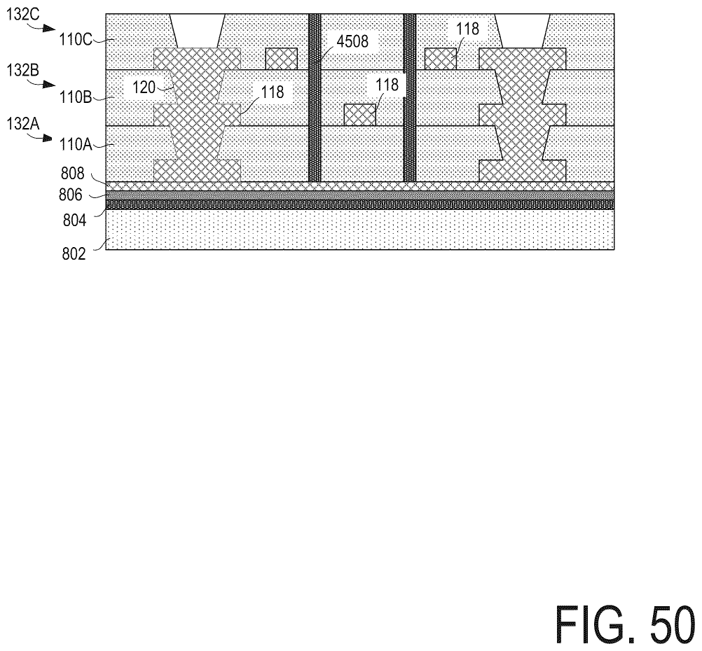

In block 4704, vias 4902 are drilled through some or all of the layers 110A-C, as shown in FIG. 49. The vias 4902 may be any suitable diameter, such as 10-100 micrometers. In block 4706, the vias 4902 are filled with magnetic paste, forming the magnetic cores 4508, as shown in FIG. 50.

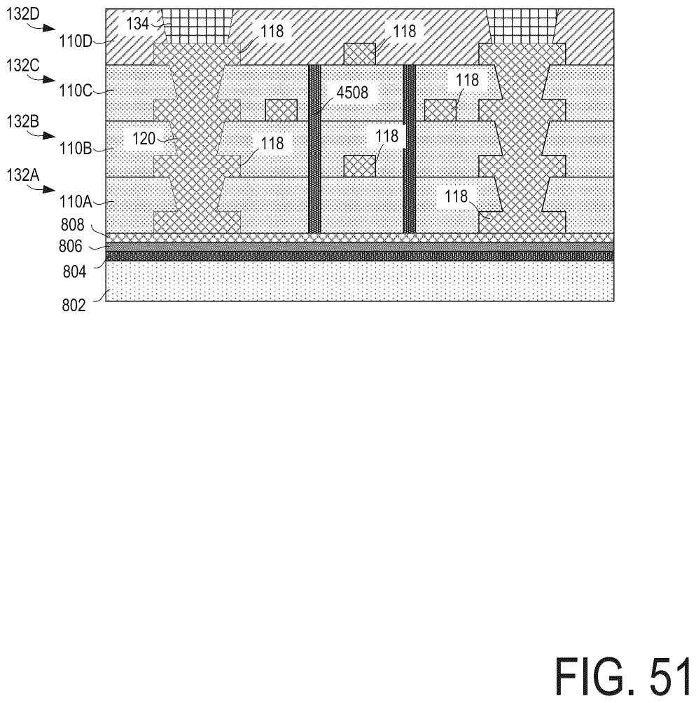

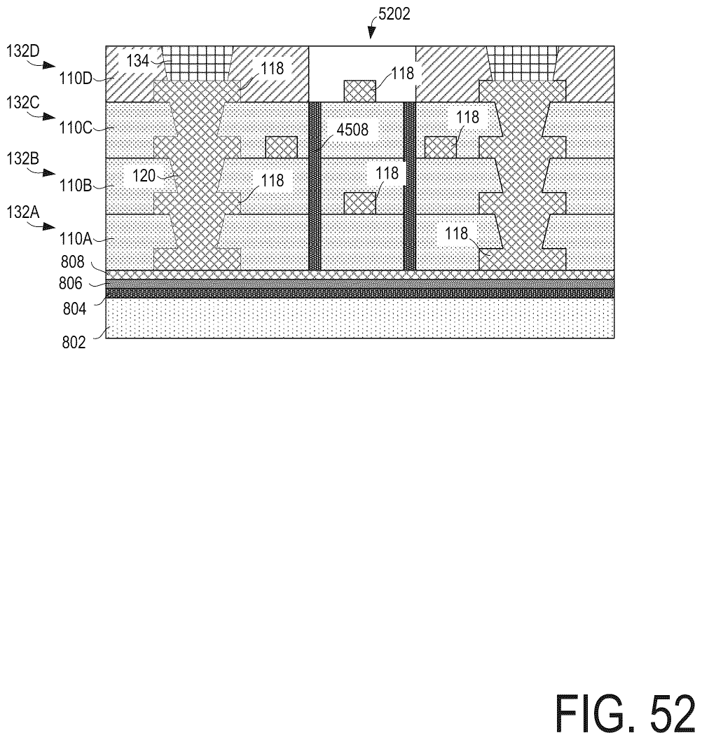

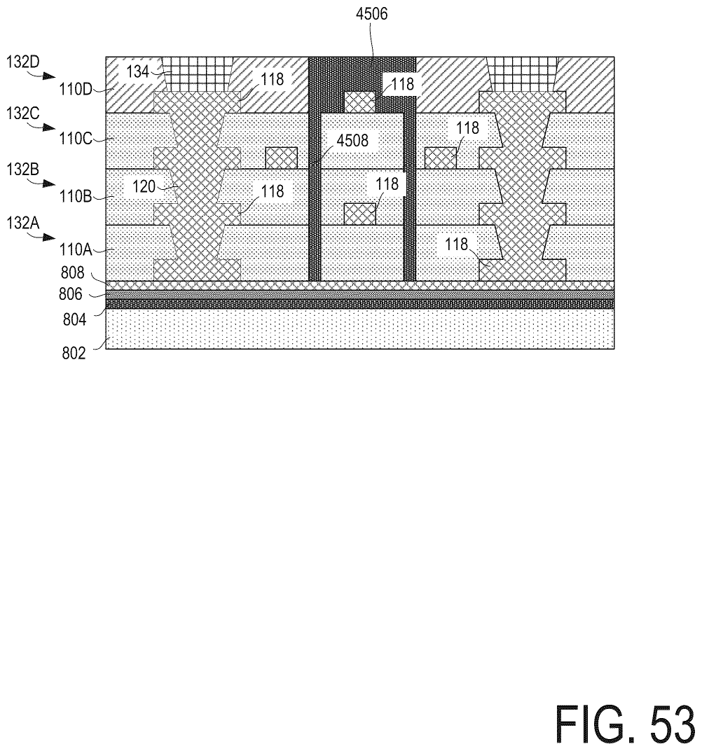

In block 4708, a solder resist lamination layer 110D may be deposited as the last layer, with pads/vias with a conductive material such as a Cu—Ni—Sn alloy, as shown in FIG. 51. In block 4710, one or more cavities 5202 is formed in the solder resist lamination layer 110D, as shown in FIG. 52. In block 4712, the cavity 5202 is filled with magnetic paste, forming magnetic cap 4506, as shown in FIG. 53.

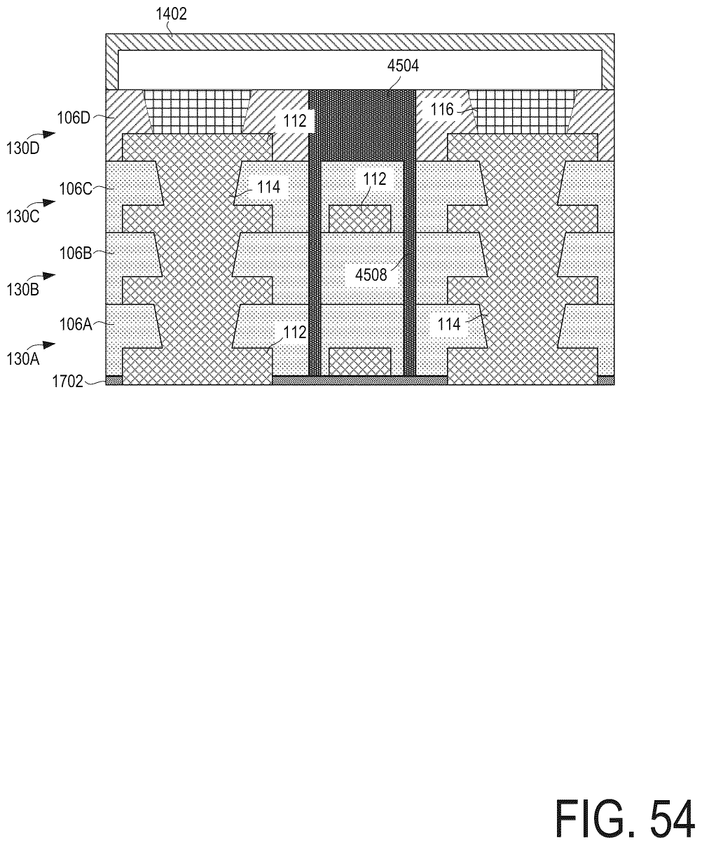

In block 4714, another part of the substrate is formed on a glass carrier 802 with relatively thick traces. Part of the creation of the part of the substrate may be similar to blocks 334-338 in the method 300, a description of which will not be repeated in the interest of clarity. A magnetic cap 4504 may be formed in the solder resist lamination layer 106D in a similar manner as the magnetic cap 4506, a description of which will not be repeated in the interest of clarity. The part of the substrate with the magnetic cap 4504 is shown in FIG. 53. The part of the substrate may be removed from the glass carrier 802 and be further processed in a similar manner as blocks 354-362 to result in the part of the substrate shown in FIG. 54.

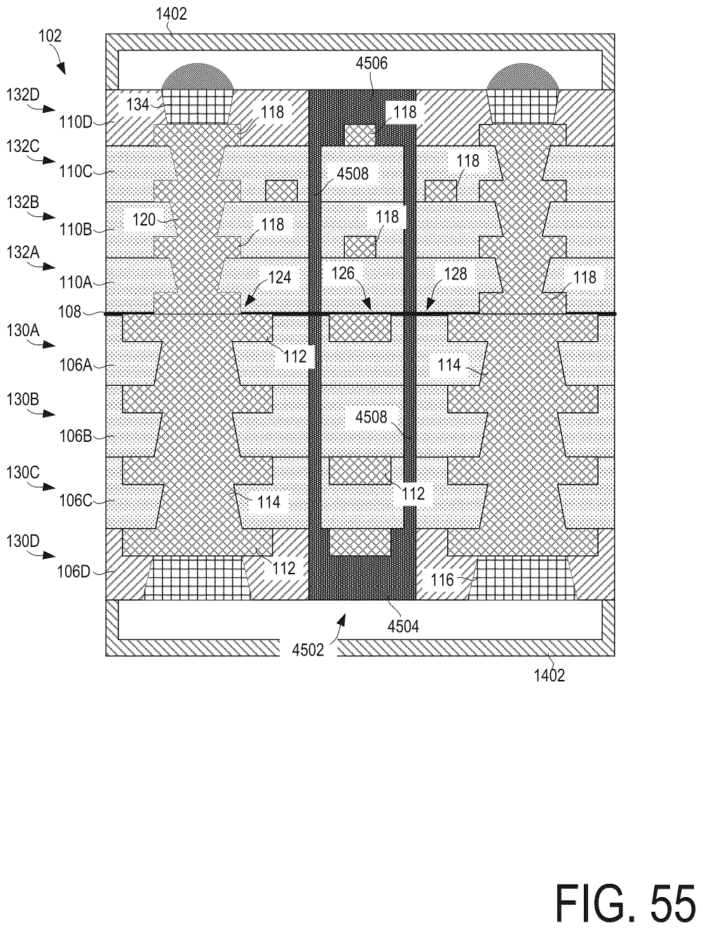

In block 4716, the parts of the substrate are bonded together, as shown in FIG. 55. The surfaces to be bonded together are cleaned and otherwise prepared for bonding. A chemical mechanical polishing (CMP) process can be carried out to control undulation and roughness to the submicron scale. A wet (chemical) or dry (plasma) process can be used to prepare the copper surfaces to be free of any oxide or foreign material. The substrate parts are aligned using fiducial marks on the substrate parts and may then be clamped together. The substrate parts may be placed in a vacuum furnace at a temperature of around 150° C. for 30 minutes to establish the hybrid bond. The substrate 102 can be annealed at a temperature of 200° C. for 30 minutes to remove any residual stress and promote grain growth to improve both the interfacial strength and electrical conductivity.

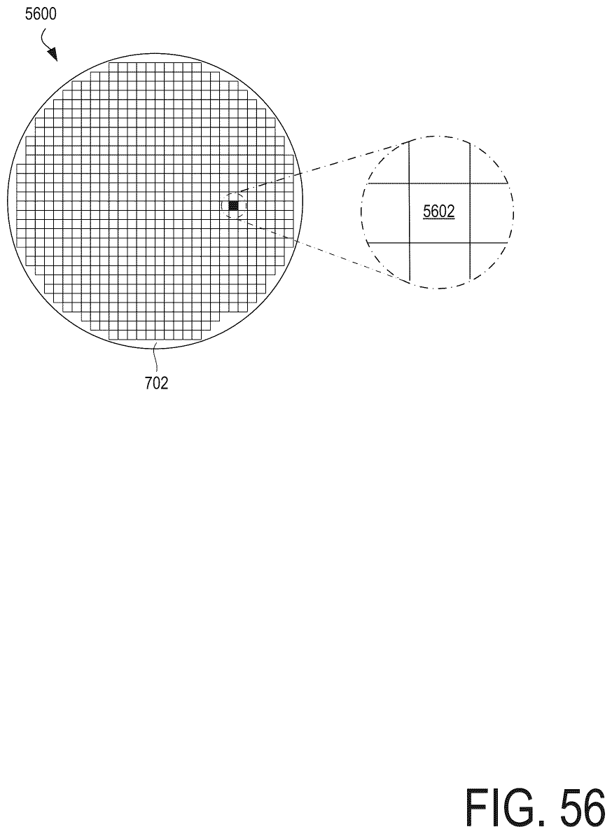

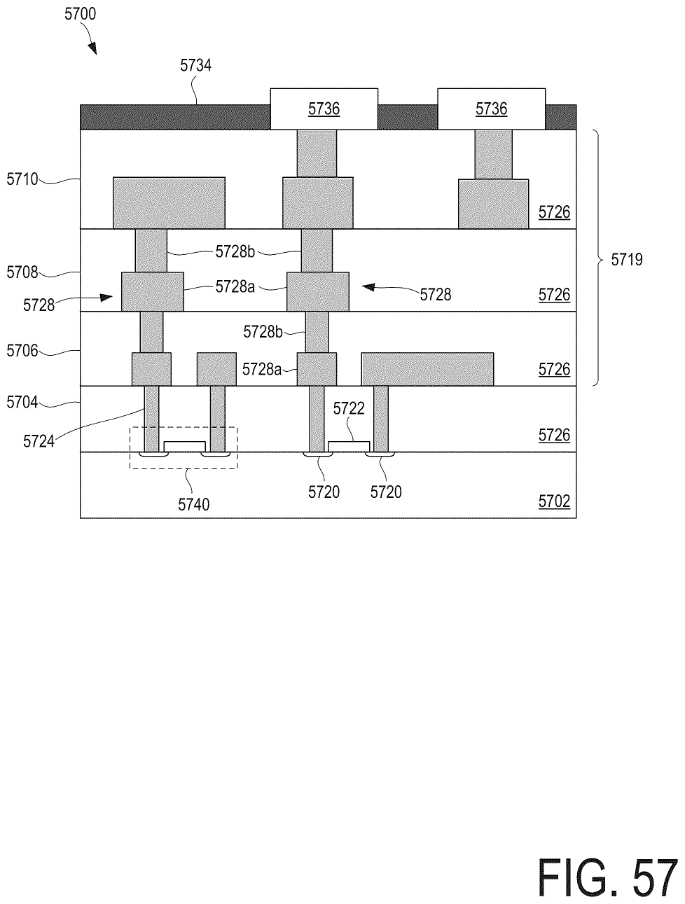

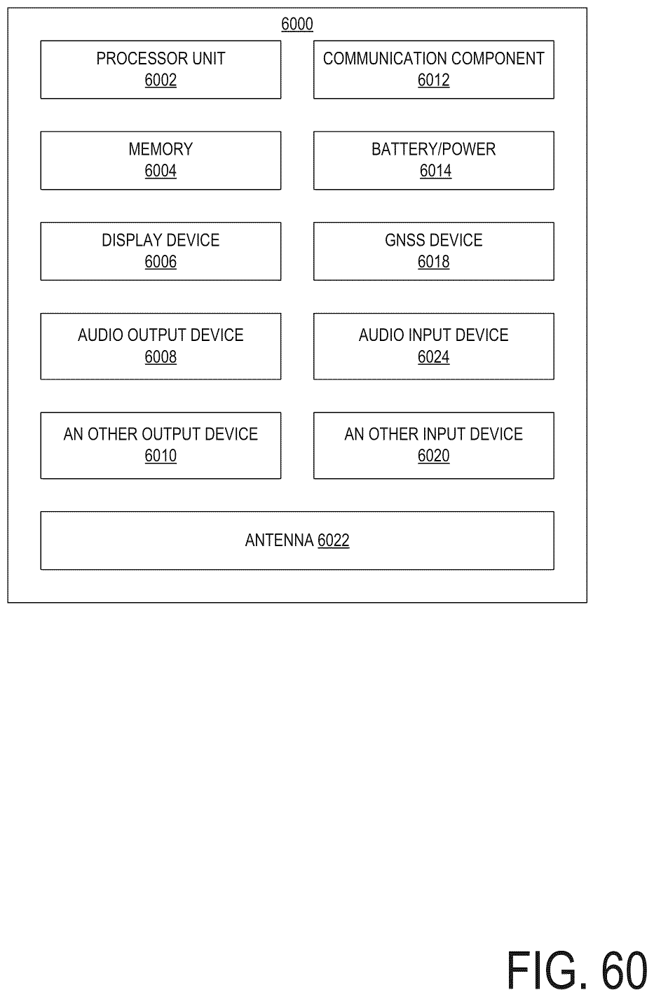

FIG. 56 is a top view of a wafer 5600 and dies 5602 that may be included in any of the integrated circuit components 100 disclosed herein (e.g., as any suitable ones of the dies 104). The wafer 5600 may be composed of semiconductor material and may include one or more dies 5602 having integrated circuit structures formed on a surface of the wafer 5600. The individual dies 5602 may be a repeating unit of an integrated circuit product that includes any suitable integrated circuit. After the fabrication of the semiconductor product is complete, the wafer 5600 may undergo a singulation process in which the dies 5602 are separated from one another to provide discrete “chips” of the integrated circuit product. The die 5602 may be any of the dies 104 disclosed herein. The die 5602 may include one or more transistors (e.g., some of the transistors 5740 of FIG. 57, discussed below), supporting circuitry to route electrical signals to the transistors, passive components (e.g., signal traces, resistors, capacitors, or inductors), and/or any other integrated circuit components. In some embodiments, the wafer 5600 or the die 5602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 5602. For example, a memory array formed by multiple memory devices may be formed on a same die 5602 as a processor unit (e.g., the processor unit 6002 of FIG. 60) or other logic that is configured to store information in the memory devices or execute instructions stored in the memory array. Various ones of the integrated circuit components 100 disclosed herein may be manufactured using a die-to-wafer assembly technique in which some dies 104 are attached to a wafer 5600 that include others of the dies 104, and the wafer 5600 is subsequently singulated.

FIG. 57 is a cross-sectional side view of an integrated circuit device 5700 that may be included in any of the integrated circuit components 100 disclosed herein (e.g., in any of the dies 104). One or more of the integrated circuit devices 5700 may be included in one or more dies 5602 (FIG. 56). The integrated circuit device 5700 may be formed on a die substrate 5702 (e.g., the wafer 5600 of FIG. 56) and may be included in a die (e.g., the die 5602 of FIG. 56). The die substrate 5702 may be a semiconductor substrate composed of semiconductor material systems including, for example, n-type or p-type materials systems (or a combination of both). The die substrate 5702 may include, for example, a crystalline substrate formed using a bulk silicon or a silicon-on-insulator (SOI) substructure. In some embodiments, the die substrate 5702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 5702. Although a few examples of materials from which the die substrate 5702 may be formed are described here, any material that may serve as a foundation for an integrated circuit device 5700 may be used. The die substrate 5702 may be part of a singulated die (e.g., the dies 5602 of FIG. 56) or a wafer (e.g., the wafer 5600 of FIG. 56).

The integrated circuit device 5700 may include one or more device layers 5704 disposed on the die substrate 5702. The device layer 5704 may include features of one or more transistors 5740 (e.g., metal oxide semiconductor field-effect transistors (MOSFETs)) formed on the die substrate 5702. The transistors 5740 may include, for example, one or more source and/or drain (S/D) regions 5720, a gate 5722 to control current flow between the S/D regions 5720, and one or more S/D contacts 5724 to route electrical signals to/from the S/D regions 5720. The transistors 5740 may include additional features not depicted for the sake of clarity, such as device isolation regions, gate contacts, and the like. The transistors 5740 are not limited to the type and configuration depicted in FIG. 57 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

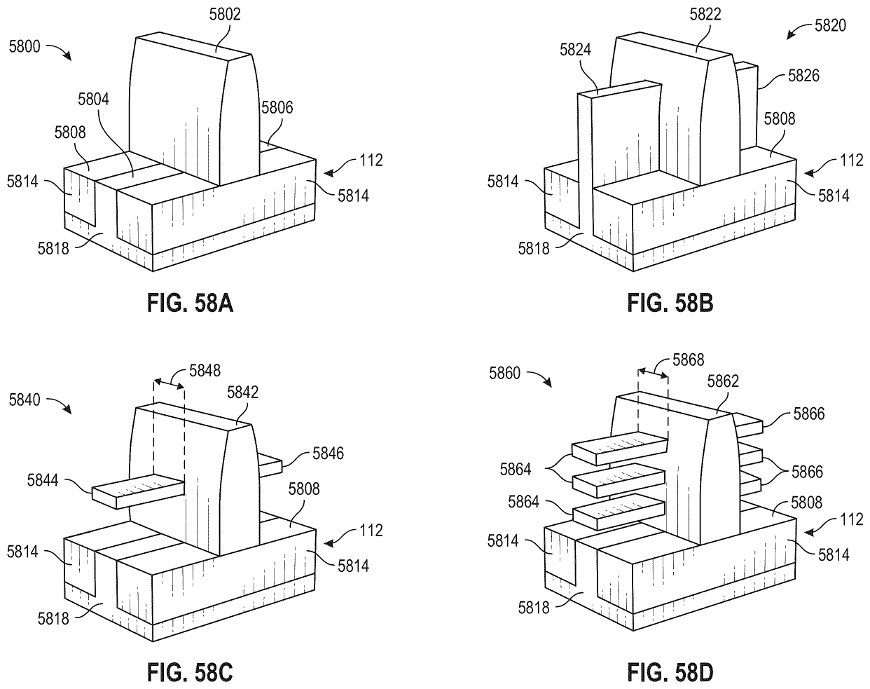

FIGS. 58A-58D are simplified perspective views of example planar, FinFET, gate-all-around, and stacked gate-all-around transistors. The transistors illustrated in FIGS. 58A-58D are formed on a substrate 5816 having a surface 5808. Isolation regions 5814 separate the source and drain regions of the transistors from other transistors and from a bulk region 5818 of the substrate 5816.

FIG. 58A is a perspective view of an example planar transistor 5800 comprising a gate 5802 that controls current flow between a source region 5804 and a drain region 5806. The transistor 5800 is planar in that the source region 5804 and the drain region 5806 are planar with respect to the substrate surface 5808.

FIG. 58B is a perspective view of an example FinFET transistor 5820 comprising a gate 5822 that controls current flow between a source region 5824 and a drain region 5826. The transistor 5820 is non-planar in that the source region 5824 and the drain region 5826 comprise “fins” that extend upwards from the substrate surface 5828. As the gate 5822 encompasses three sides of the semiconductor fin that extends from the source region 5824 to the drain region 5826, the transistor 5820 can be considered a tri-gate transistor. FIG. 58B illustrates one S/D fin extending through the gate 5822, but multiple S/D fins can extend through the gate of a FinFET transistor.

FIG. 58C is a perspective view of a gate-all-around (GAA) transistor 5840 comprising a gate 5842 that controls current flow between a source region 5844 and a drain region 5846. The transistor 5840 is non-planar in that the source region 5844 and the drain region 5846 are elevated from the substrate surface 5828.

FIG. 58D is a perspective view of a GAA transistor 5860 comprising a gate 5862 that controls current flow between multiple elevated source regions 5864 and multiple elevated drain regions 5866. The transistor 5860 is a stacked GAA transistor as the gate controls the flow of current between multiple elevated S/D regions stacked on top of each other. The transistors 5840 and 5860 are considered gate-all-around transistors as the gates encompass all sides of the semiconductor portions that extends from the source regions to the drain regions. The transistors 5840 and 5860 can alternatively be referred to as nanowire, nanosheet, or nanoribbon transistors depending on the width (e.g., widths 5848 and 5868 of transistors 5840 and 5860, respectively) of the semiconductor portions extending through the gate.

Returning to FIG. 57, a transistor 5740 may include a gate 5722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 5740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 5740 along the source-channel-drain direction, the gate electrode may consist of a U-shaped structure that includes a bottom portion substantially parallel to the surface of the die substrate 5702 and two sidewall portions that are substantially perpendicular to the top surface of the die substrate 5702. In other embodiments, at least one of the metal layers that form the gate electrode may simply be a planar layer that is substantially parallel to the top surface of the die substrate 5702 and does not include sidewall portions substantially perpendicular to the top surface of the die substrate 5702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 5720 may be formed within the die substrate 5702 adjacent to the gate 5722 of individual transistors 5740. The S/D regions 5720 may be formed using an implantation/diffusion process or an etching/deposition process, for example. In the former process, dopants such as boron, aluminum, antimony, phosphorous, or arsenic may be ion-implanted into the die substrate 5702 to form the S/D regions 5720. An annealing process that activates the dopants and causes them to diffuse farther into the die substrate 5702 may follow the ion-implantation process. In the latter process, the die substrate 5702 may first be etched to form recesses at the locations of the S/D regions 5720. An epitaxial deposition process may then be carried out to fill the recesses with material that is used to fabricate the S/D regions 5720. In some implementations, the S/D regions 5720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 5720 may be formed using one or more alternate semiconductor materials such as germanium or a group III-V material or alloy. In further embodiments, one or more layers of metal and/or metal alloys may be used to form the S/D regions 5720.

Electrical signals, such as power and/or input/output (I/O) signals, may be routed to and/or from the devices (e.g., transistors 5740) of the device layer 5704 through one or more interconnect layers disposed on the device layer 5704 (illustrated in FIG. 57 as interconnect layers 5706-5710). For example, electrically conductive features of the device layer 5704 (e.g., the gate 5722 and the S/D contacts 5724) may be electrically coupled with the interconnect structures 5728 of the interconnect layers 5706-5710. The one or more interconnect layers 5706-5710 may form a metallization stack (also referred to as an “ILD stack”) 5719 of the integrated circuit device 5700.

The interconnect structures 5728 may be arranged within the interconnect layers 5706-5710 to route electrical signals according to a wide variety of designs; in particular, the arrangement is not limited to the particular configuration of interconnect structures 5728 depicted in FIG. 57. Although a particular number of interconnect layers 5706-5710 is depicted in FIG. 57, embodiments of the present disclosure include integrated circuit devices having more or fewer interconnect layers than depicted.

In some embodiments, the interconnect structures 5728 may include lines 5728a and/or vias 5728b filled with an electrically conductive material such as a metal. The lines 5728a may be arranged to route electrical signals in a direction of a plane that is substantially parallel with a surface of the die substrate 5702 upon which the device layer 5704 is formed. For example, the lines 5728a may route electrical signals in a direction in and out of the page and/or in a direction across the page. The vias 5728b may be arranged to route electrical signals in a direction of a plane that is substantially perpendicular to the surface of the die substrate 5702 upon which the device layer 5704 is formed. In some embodiments, the vias 5728b may electrically couple lines 5728a of different interconnect layers 5706-5710 together.

The interconnect layers 5706-5710 may include a dielectric material 5726 disposed between the interconnect structures 5728, as shown in FIG. 57. In some embodiments, dielectric material 5726 disposed between the interconnect structures 5728 in different ones of the interconnect layers 5706-5710 may have different compositions; in other embodiments, the composition of the dielectric material 5726 between different interconnect layers 5706-5710 may be the same. The device layer 5704 may include a dielectric material 5726 disposed between the transistors 5740 and a bottom layer of the metallization stack as well. The dielectric material 5726 included in the device layer 5704 may have a different composition than the dielectric material 5726 included in the interconnect layers 5706-5710; in other embodiments, the composition of the dielectric material 5726 in the device layer 5704 may be the same as a dielectric material 5726 included in any one of the interconnect layers 5706-5710.

A first interconnect layer 5706 (referred to as Metal 1 or “M1”) may be formed directly on the device layer 5704. In some embodiments, the first interconnect layer 5706 may include lines 5728a and/or vias 5728b, as shown. The lines 5728a of the first interconnect layer 5706 may be coupled with contacts (e.g., the S/D contacts 5724) of the device layer 5704. The vias 5728b of the first interconnect layer 5706 may be coupled with the lines 5728a of a second interconnect layer 5708.

The second interconnect layer 5708 (referred to as Metal 2 or “M2”) may be formed directly on the first interconnect layer 5706. In some embodiments, the second interconnect layer 5708 may include via 5728b to couple the lines 5728 of the second interconnect layer 5708 with the lines 5728a of a third interconnect layer 5710. Although the lines 5728a and the vias 5728b are structurally delineated with a line within individual interconnect layers for the sake of clarity, the lines 5728a and the vias 5728b may be structurally and/or materially contiguous (e.g., simultaneously filled during a dual-damascene process) in some embodiments.

The third interconnect layer 5710 (referred to as Metal 3 or “M3”) (and additional interconnect layers, as desired) may be formed in succession on the second interconnect layer 5708 according to similar techniques and configurations described in connection with the second interconnect layer 5708 or the first interconnect layer 5706. In some embodiments, the interconnect layers that are “higher up” in the metallization stack 5719 in the integrated circuit device 5700 (i.e., farther away from the device layer 5704) may be thicker that the interconnect layers that are lower in the metallization stack 5719, with lines 5728a and vias 5728b in the higher interconnect layers being thicker than those in the lower interconnect layers.

The integrated circuit device 5700 may include a solder resist material 5734 (e.g., polyimide or similar material) and one or more conductive contacts 5736 formed on the interconnect layers 5706-5710. In FIG. 57, the conductive contacts 5736 are illustrated as taking the form of bond pads. The conductive contacts 5736 may be electrically coupled with the interconnect structures 5728 and configured to route the electrical signals of the transistor(s) 5740 to external devices. For example, solder bonds may be formed on the one or more conductive contacts 5736 to mechanically and/or electrically couple an integrated circuit die including the integrated circuit device 5700 with another component (e.g., a printed circuit board). The integrated circuit device 5700 may include additional or alternate structures to route the electrical signals from the interconnect layers 5706-5710; for example, the conductive contacts 5736 may include other analogous features (e.g., posts) that route the electrical signals to external components. The conductive contacts 5736 may serve as the conductive contacts 112, 116, 118, 134, as appropriate.

In some embodiments in which the integrated circuit device 5700 is a double-sided die, the integrated circuit device 5700 may include another metallization stack (not shown) on the opposite side of the device layer(s) 5704. This metallization stack may include multiple interconnect layers as discussed above with reference to the interconnect layers 5706-5710, to provide conductive pathways (e.g., including conductive lines and vias) between the device layer(s) 5704 and additional conductive contacts (not shown) on the opposite side of the integrated circuit device 5700 from the conductive contacts 5736. These additional conductive contacts may serve as the conductive contacts 112, 116, 118, 134, as appropriate.

In other embodiments in which the integrated circuit device 5700 is a double-sided die, the integrated circuit device 5700 may include one or more through silicon vias (TSVs) through the die substrate 5702; these TSVs may make contact with the device layer(s) 5704, and may provide conductive pathways between the device layer(s) 5704 and additional conductive contacts (not shown) on the opposite side of the integrated circuit device 5700 from the conductive contacts 5736. These additional conductive contacts may serve as the conductive contacts 112, 116, 118, 134, as appropriate. In some embodiments, TSVs extending through the substrate can be used for routing power and ground signals from conductive contacts on the opposite side of the integrated circuit device 5700 from the conductive contacts 5736 to the transistors 5740 and any other components integrated into the die 5700, and the metallization stack 5719 can be used to route I/O signals from the conductive contacts 5736 to transistors 5740 and any other components integrated into the die 5700.

Multiple integrated circuit devices 5700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

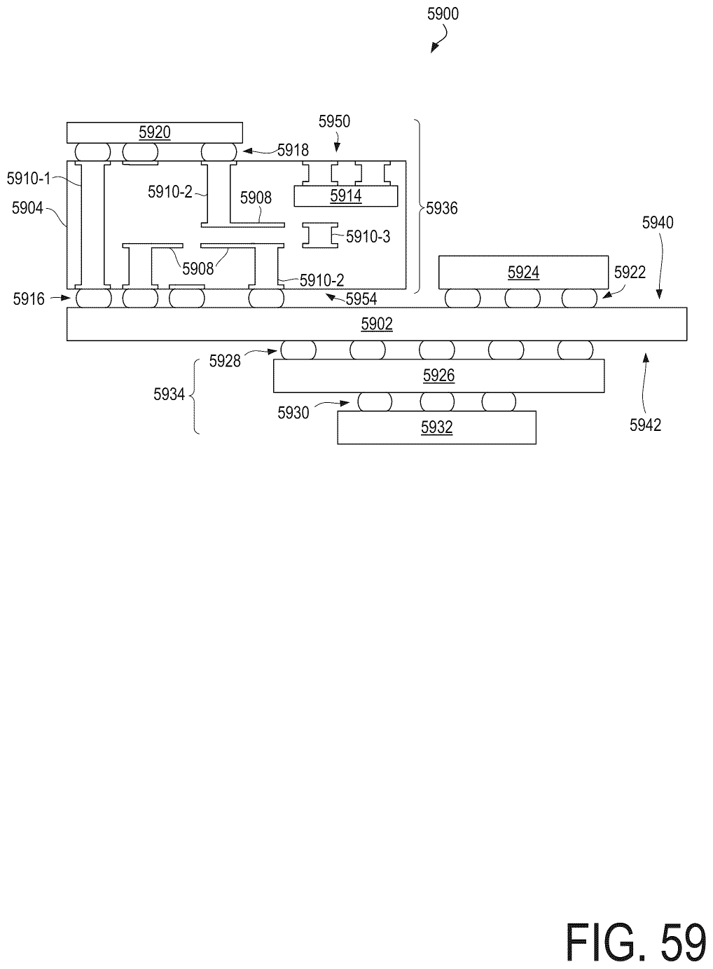

FIG. 59 is a cross-sectional side view of an integrated circuit device assembly 5900 that may include any of the integrated circuit components 100 disclosed herein. In some embodiments, the integrated circuit device assembly 5900 may be an integrated circuit components 100. The integrated circuit device assembly 5900 includes a number of components disposed on a circuit board 5902 (which may be a motherboard, system board, mainboard, etc.). The integrated circuit device assembly 5900 includes components disposed on a first face 5940 of the circuit board 5902 and an opposing second face 5942 of the circuit board 5902; generally, components may be disposed on one or both faces 5940 and 5942. Any of the integrated circuit components discussed below with reference to the integrated circuit device assembly 5900 may take the form of any suitable ones of the embodiments of the integrated circuit components 100 disclosed herein.

In some embodiments, the circuit board 5902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 5902. In other embodiments, the circuit board 5902 may be a non-PCB substrate. In some embodiments the circuit board 5902 may be, for example, the substrates 102, 3002, 3702, 4502. The integrated circuit device assembly 5900 illustrated in FIG. 59 includes a package-on-interposer structure 5936 coupled to the first face 5940 of the circuit board 5902 by coupling components 5916. The coupling components 5916 may electrically and mechanically couple the package-on-interposer structure 5936 to the circuit board 5902, and may include solder balls (as shown in FIG. 59), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 5916 may serve as the coupling components illustrated or described for any of the substrate assembly or substrate assembly components described herein, as appropriate.

The package-on-interposer structure 5936 may include an integrated circuit component 5920 coupled to an interposer 5904 by coupling components 5918. The coupling components 5918 may take any suitable form for the application, such as the forms discussed above with reference to the coupling components 5916. Although a single integrated circuit component 5920 is shown in FIG. 59, multiple integrated circuit components may be coupled to the interposer 5904; indeed, additional interposers may be coupled to the interposer 5904. The interposer 5904 may provide an intervening substrate used to bridge the circuit board 5902 and the integrated circuit component 5920.

The integrated circuit component 5920 may be a packaged or unpacked integrated circuit product that includes one or more integrated circuit dies (e.g., the die 5602 of FIG. 56, the integrated circuit device 5700 of FIG. 57) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 5920, a single monolithic integrated circuit die comprises solder bumps attached to contacts on the die. The solder bumps allow the die to be directly attached to the interposer 5904. The integrated circuit component 5920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 5920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 5920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 5920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 5904 may spread connections to a wider pitch or reroute a connection to a different connection. For example, the interposer 5904 may couple the integrated circuit component 5920 to a set of ball grid array (BGA) conductive contacts of the coupling components 5916 for coupling to the circuit board 5902. In the embodiment illustrated in FIG. 59, the integrated circuit component 5920 and the circuit board 5902 are attached to opposing sides of the interposer 5904; in other embodiments, the integrated circuit component 5920 and the circuit board 5902 may be attached to a same side of the interposer 5904. In some embodiments, three or more components may be interconnected by way of the interposer 5904.

In some embodiments, the interposer 5904 may be formed as a PCB, including multiple metal layers separated from one another by layers of dielectric material and interconnected by electrically conductive vias. In some embodiments, the interposer 5904 may be formed of an epoxy resin, a fiberglass-reinforced epoxy resin, an epoxy resin with inorganic fillers, a ceramic material, or a polymer material such as polyimide. In some embodiments, the interposer 5904 may be formed of alternate rigid or flexible materials that may include the same materials described above for use in a semiconductor substrate, such as silicon, germanium, and other group III-V and group IV materials. The interposer 5904 may include metal interconnects 5908 and vias 5910, including but not limited to through hole vias 5910-1 (that extend from a first face 5950 of the interposer 5904 to a second face 5954 of the interposer 5904), blind vias 5910-2 (that extend from the first or second faces 5950 or 5954 of the interposer 5904 to an internal metal layer), and buried vias 5910-3 (that connect internal metal layers).

In some embodiments, the interposer 5904 can comprise a silicon interposer. Through silicon vias (TSV) extending through the silicon interposer can connect connections on a first face of a silicon interposer to an opposing second face of the silicon interposer. In some embodiments, an interposer 5904 comprising a silicon interposer can further comprise one or more routing layers to route connections on a first face of the interposer 5904 to an opposing second face of the interposer 5904.

The interposer 5904 may further include embedded devices 5914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 5904. The package-on-interposer structure 5936 may take the form of any of the package-on-interposer structures known in the art.

The integrated circuit device assembly 5900 may include an integrated circuit component 5924 coupled to the first face 5940 of the circuit board 5902 by coupling components 5922. The coupling components 5922 may take the form of any of the embodiments discussed above with reference to the coupling components 5916, and the integrated circuit component 5924 may take the form of any of the embodiments discussed above with reference to the integrated circuit component 5920.

The integrated circuit device assembly 5900 illustrated in FIG. 59 includes a package-on-package structure 5934 coupled to the second face 5942 of the circuit board 5902 by coupling components 5928. The package-on-package structure 5934 may include an integrated circuit component 5926 and an integrated circuit component 5932 coupled together by coupling components 5930 such that the integrated circuit component 5926 is disposed between the circuit board 5902 and the integrated circuit component 5932. The coupling components 5928 and 5930 may take the form of any of the embodiments of the coupling components 5916 discussed above, and the integrated circuit components 5926 and 5932 may take the form of any of the embodiments of the integrated circuit component 5920 discussed above. The package-on-package structure 5934 may be configured in accordance with any of the package-on-package structures known in the art.

FIG. 60 is a block diagram of an example electrical device 6000 that may include one or more of the integrated circuit components 100 disclosed herein. For example, any suitable ones of the components of the electrical device 6000 may include one or more of the integrated circuit device assemblies 5900, integrated circuit components 5920, integrated circuit devices 5700, or integrated circuit dies 5602 disclosed herein, and may be arranged in any of the integrated circuit components 100 disclosed herein. A number of components are illustrated in FIG. 60 as included in the electrical device 6000, but any one or more of these components may be omitted or duplicated, as suitable for the application. In some embodiments, some or all of the components included in the electrical device 6000 may be attached to one or more motherboards mainboards, or system boards. In some embodiments, one or more of these components are fabricated onto a single system-on-a-chip (SoC) die.

Additionally, in various embodiments, the electrical device 6000 may not include one or more of the components illustrated in FIG. 60, but the electrical device 6000 may include interface circuitry for coupling to the one or more components. For example, the electrical device 6000 may not include a display device 6006, but may include display device interface circuitry (e.g., a connector and driver circuitry) to which a display device 6006 may be coupled. In another set of examples, the electrical device 6000 may not include an audio input device 6024 or an audio output device 6008, but may include audio input or output device interface circuitry (e.g., connectors and supporting circuitry) to which an audio input device 6024 or audio output device 6008 may be coupled.

The electrical device 6000 may include one or more processor units 6002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 6002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 6000 may include a memory 6004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 6004 may include memory that is located on the same integrated circuit die as the processor unit 6002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 6000 can comprise one or more processor units 6002 that are heterogeneous or asymmetric to another processor unit 6002 in the electrical device 6000. There can be a variety of differences between the processing units 6002 in a system in terms of a spectrum of metrics of merit including architectural, microarchitectural, thermal, power consumption characteristics, and the like. These differences can effectively manifest themselves as asymmetry and heterogeneity among the processor units 6002 in the electrical device 6000.

In some embodiments, the electrical device 6000 may include a communication component 6012 (e.g., one or more communication components). For example, the communication component 6012 can manage wireless communications for the transfer of data to and from the electrical device 6000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 6012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 6012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 6012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 6012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 6012 may operate in accordance with other wireless protocols in other embodiments. The electrical device 6000 may include an antenna 6022 to facilitate wireless communications and/or to receive other wireless communications (such as AM or FM radio transmissions).

In some embodiments, the communication component 6012 may manage wired communications, such as electrical, optical, or any other suitable communication protocols (e.g., IEEE 802.3 Ethernet standards). As noted above, the communication component 6012 may include multiple communication components. For instance, a first communication component 6012 may be dedicated to shorter-range wireless communications such as Wi-Fi or Bluetooth, and a second communication component 6012 may be dedicated to longer-range wireless communications such as global positioning system (GPS), EDGE, GPRS, CDMA, WiMAX, LTE, EV-DO, or others. In some embodiments, a first communication component 6012 may be dedicated to wireless communications, and a second communication component 6012 may be dedicated to wired communications.

The electrical device 6000 may include battery/power circuitry 6014. The battery/power circuitry 6014 may include one or more energy storage devices (e.g., batteries or capacitors) and/or circuitry for coupling components of the electrical device 6000 to an energy source separate from the electrical device 6000 (e.g., AC line power).

The electrical device 6000 may include a display device 6006 (or corresponding interface circuitry, as discussed above). The display device 6006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 6000 may include an audio output device 6008 (or corresponding interface circuitry, as discussed above). The audio output device 6008 may include any embedded or wired or wirelessly connected external device that generates an audible indicator, such speakers, headsets, or earbuds.

The electrical device 6000 may include an audio input device 6024 (or corresponding interface circuitry, as discussed above). The audio input device 6024 may include any embedded or wired or wirelessly connected device that generates a signal representative of a sound, such as microphones, microphone arrays, or digital instruments (e.g., instruments having a musical instrument digital interface (MIDI) output). The electrical device 6000 may include a Global Navigation Satellite System (GNSS) device 6018 (or corresponding interface circuitry, as discussed above), such as a Global Positioning System (GPS) device. The GNSS device 6018 may be in communication with a satellite-based system and may determine a geolocation of the electrical device 6000 based on information received from one or more GNSS satellites, as known in the art.

The electrical device 6000 may include an other output device 6010 (or corresponding interface circuitry, as discussed above). Examples of the other output device 6010 may include an audio codec, a video codec, a printer, a wired or wireless transmitter for providing information to other devices, or an additional storage device.

The electrical device 6000 may include an other input device 6020 (or corresponding interface circuitry, as discussed above). Examples of the other input device 6020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 6000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 6000 may be any other electronic device that processes data. In some embodiments, the electrical device 6000 may comprise multiple discrete physical components. Given the range of devices that the electrical device 6000 can be manifested as in various embodiments, in some embodiments, the electrical device 6000 can be referred to as a computing device or a computing system.

### Examples

Illustrative examples of the technologies disclosed herein are provided below. An embodiment of the technologies may include any one or more, and any combination of, the examples described below.

Example 1 includes a device comprising a substrate comprising a first plurality of layers, wherein individual layers of the first plurality of layers comprises a plurality of conductive traces with a first height; and a second plurality of layers adjacent the first plurality of layers, wherein individual layers of the second plurality of layers comprises a plurality of conductive traces with a second height, wherein the second height is at least 1.5 times the first height, wherein, at an interface between the first plurality of layers and the second plurality of layers, a hybrid bond joins the first plurality of layers and the second plurality of layers, wherein the hybrid bond comprises one or more direct bonds between one or more conductive traces of the first plurality of layers and one or more conductive traces of the second plurality of layers.

Example 2 includes the subject matter of Example 1, and wherein the first plurality of layers comprises a substrate core, wherein one or more vias are defined in the substrate core, wherein individual vias of the one or more vias extend from a top surface of the substrate core to a bottom surface of the substrate core.

Example 3 includes the subject matter of any of Examples 1 and 2, and wherein individual vias of the one or more vias are filled with a magnetic lining surrounding a conductive material.

Example 4 includes the subject matter of any of Examples 1-3, and wherein the substrate does not include a substrate core, wherein one or more vias are defined through the first plurality of layers and the second plurality of layers, wherein individual vias of the one or more vias are filled with a magnetic material.

Example 5 includes the subject matter of any of Examples 1-4, and wherein one or more vias are defined in the substrate, wherein individual vias of the one or more vias are at least partially filled with a magnetic material.

Example 6 includes the subject matter of any of Examples 1-5, and wherein the magnetic material has a relative permeability over 100.

Example 7 includes the subject matter of any of Examples 1-6, and further including a die mounted on the substrate, wherein the substrate comprises one or more traces that are to provide power to the die.

Example 8 includes the subject matter of any of Examples 1-7, and wherein the magnetic material stabilizes a voltage and/or current provided by the one or more traces that are to provide power to the die.

Example 9 includes the subject matter of any of Examples 1-8, and wherein the hybrid bond further comprises a dielectric bond between a dielectric material of the first plurality of layers and a dielectric material of the second plurality of layers.

Example 10 includes the subject matter of any of Examples 1-9, and wherein the hybrid bond further comprises a bond between one or more conductive traces of the first plurality of layers and the dielectric material of the second plurality of layers.

Example 11 includes the subject matter of any of Examples 1-10, and wherein the dielectric material comprises carbon and hydrogen.

Example 12 includes the subject matter of any of Examples 1-11, and wherein the dielectric material comprises silicon and oxygen.

Example 13 includes the subject matter of any of Examples 1-12, and wherein the dielectric material comprises silicon and nitrogen.

Example 14 includes the subject matter of any of Examples 1-13, and wherein the first height is between 12 and 18 micrometers, wherein the second height is between 22 and 28 micrometers.

Example 15 includes the subject matter of any of Examples 1-14, and wherein individual conductive traces of the plurality of conductive traces of the first plurality of layers comprise copper, wherein individual conductive traces of the plurality of conductive traces of the second plurality of layers comprise copper.

Example 16 includes the subject matter of any of Examples 1-15, and further including a die mounted on the substrate, wherein the die is a processor die.

Example 17 includes the subject matter of any of Examples 1-16, and wherein the device is a compute device comprising a memory coupled to the processor die.

Example 18 includes a device comprising a substrate comprising a first plurality of layers, wherein individual layers of the first plurality of layers comprises a plurality of conductive traces with a first height; and a second plurality of layers adjacent the first plurality of layers, wherein individual layers of the second plurality of layers comprises a plurality of conductive traces with a second height, wherein the second height is at least 1.5 times the first height, means for joining the first plurality of layers and the second plurality of layers.

Example 19 includes the subject matter of Example 18, and wherein the means for joining the first plurality of layers and the second plurality of layers comprises a metal-metal fusion bond.

Example 20 includes the subject matter of any of Examples 18 and 19, and wherein the means for joining the first plurality of layers and the second plurality of layers comprises a copper-copper fusion bond.

Example 21 includes the subject matter of any of Examples 18-20, and further including a die mounted on the substrate, wherein the substrate comprises one or more traces that are to provide power to the die, wherein the substrate further comprises means for increasing an inductance of the one or more traces that are to provide power to the die.

Example 22 includes the subject matter of any of Examples 18-21, and wherein the first plurality of layers comprises a substrate core, wherein one or more vias are defined in the substrate core, wherein individual vias of the one or more vias extend from a top surface of the substrate core to a bottom surface of the substrate core.

Example 23 includes the subject matter of any of Examples 18-22, and wherein individual vias of the one or more vias are filled with a magnetic lining surrounding a conductive material.

Example 24 includes the subject matter of any of Examples 18-23, and wherein the substrate does not include a substrate core, wherein one or more vias are defined through the first plurality of layers and the second plurality of layers, wherein individual vias of the one or more vias are filled with a magnetic material.

Example 25 includes the subject matter of any of Examples 18-24, and wherein one or more vias are defined in the substrate, wherein individual vias of the one or more vias are at least partially filled with a magnetic material.

Example 26 includes the subject matter of any of Examples 18-25, and wherein the magnetic material has a relative permeability over 100.

Example 27 includes the subject matter of any of Examples 18-26, and further including a die mounted on the substrate, wherein the substrate comprises one or more traces that are to provide power to the die.

Example 28 includes the subject matter of any of Examples 18-27, and wherein the magnetic material stabilizes a voltage and/or current provided by the one or more traces that are to provide power to the die.

Example 29 includes the subject matter of any of Examples 18-28, and wherein the hybrid bond further comprises a dielectric bond between a dielectric material of the first plurality of layers and a dielectric material of the second plurality of layers.

Example 30 includes the subject matter of any of Examples 18-29, and wherein the hybrid bond further comprises a bond between one or more conductive traces of the first plurality of layers and the dielectric material of the second plurality of layers.

Example 31 includes the subject matter of any of Examples 18-30, and wherein the dielectric material comprises carbon and hydrogen.

Example 32 includes the subject matter of any of Examples 18-31, and wherein the dielectric material comprises silicon and oxygen.

Example 33 includes the subject matter of any of Examples 18-32, and wherein the dielectric material comprises silicon and nitrogen.

Example 34 includes the subject matter of any of Examples 18-33, and wherein the first height is between 12 and 18 micrometers, wherein the second height is between 22 and 28 micrometers.

Example 35 includes the subject matter of any of Examples 18-34, and wherein individual conductive traces of the plurality of conductive traces of the first plurality of layers comprise copper, wherein individual conductive traces of the plurality of conductive traces of the second plurality of layers comprise copper.

Example 36 includes the subject matter of any of Examples 18-35, and further including a die mounted on the substrate, wherein the die is a processor die.

Example 37 includes the subject matter of any of Examples 18-36, and wherein the device is a compute device comprising a memory coupled to the processor die.

Example 38 includes a method comprising forming a first plurality of layers for a substrate, wherein forming the first plurality of layers comprises forming a plurality of conductive traces with a first height; forming a second plurality of layers for the substrate, wherein forming the first plurality of layers comprises forming a plurality of conductive traces with a second height, wherein the second height is at least 1.5 times the first height; and joining the first plurality of layers to the second plurality of layers using hybrid bonding.

Example 39 includes the subject matter of Example 38, and wherein forming the first plurality of layers comprises forming the first plurality of layers on a substrate core.

Example 40 includes the subject matter of any of Examples 38 and 39, and further including forming one or more vias in the substrate core; forming a magnetic lining in the substrate core; and filling the magnetic lining with a conductive material.

Example 41 includes the subject matter of any of Examples 38-40, and wherein forming the first plurality of layers comprises forming the first plurality of layers on a glass carrier; and separating the first plurality of layers from the glass carrier.

Example 42 includes the subject matter of any of Examples 38-41, and further including drilling one or more vias through the first plurality of layers; filling the one or more vias through the first plurality of layers with a magnetic material; drilling one or more vias through the second plurality of layers; and filling the one or more vias through the second plurality of layers with a magnetic material.

Example 43 includes the subject matter of any of Examples 38-42, and wherein the first plurality of layers comprises a substrate core, wherein one or more vias are defined in the substrate core, wherein individual vias of the one or more vias extend from a top surface of the substrate core to a bottom surface of the substrate core.

Example 44 includes the subject matter of any of Examples 38-43, and wherein individual vias of the one or more vias are filled with a magnetic lining surrounding a conductive material.

Example 45 includes the subject matter of any of Examples 38-44, and wherein the substrate does not include a substrate core, wherein one or more vias are defined through the first plurality of layers and the second plurality of layers, wherein individual vias of the one or more vias are filled with a magnetic material.

Example 46 includes the subject matter of any of Examples 38-45, and wherein one or more vias are defined in the substrate, wherein individual vias of the one or more vias are at least partially filled with a magnetic material.

Example 47 includes the subject matter of any of Examples 38-46, and wherein the magnetic material has a relative permeability over 100.

Example 48 includes the subject matter of any of Examples 38-47, and wherein a die is mounted on the substrate, wherein the substrate comprises one or more traces that are to provide power to the die.

Example 49 includes the subject matter of any of Examples 38-48, and wherein the magnetic material stabilizes a voltage and/or current provided by the one or more traces that are to provide power to the die.

Example 50 includes the subject matter of any of Examples 38-49, and wherein the hybrid bond comprises a dielectric bond between a dielectric material of the first plurality of layers and a dielectric material of the second plurality of layers.

Example 51 includes the subject matter of any of Examples 38-50, and wherein the hybrid bond further comprises a bond between one or more conductive traces of the first plurality of layers and the dielectric material of the second plurality of layers.

Example 52 includes the subject matter of any of Examples 38-51, and wherein the dielectric material comprises carbon and hydrogen.

Example 53 includes the subject matter of any of Examples 38-52, and wherein the dielectric material comprises silicon and oxygen.

Example 54 includes the subject matter of any of Examples 38-53, and wherein the dielectric material comprises silicon and nitrogen.

Example 55 includes the subject matter of any of Examples 38-54, and wherein the first height is between 12 and 18 micrometers, wherein the second height is between 22 and 28 micrometers.

Example 56 includes the subject matter of any of Examples 38-55, and wherein individual conductive traces of the plurality of conductive traces of the first plurality of layers comprise copper, wherein individual conductive traces of the plurality of conductive traces of the second plurality of layers comprise copper.

1. A device comprising:
a substrate comprising:
a first plurality of layers, wherein individual layers of the first plurality of layers comprises a plurality of conductive traces with a first height; and
a second plurality of layers adjacent the first plurality of layers, wherein individual layers of the second plurality of layers comprises a plurality of conductive traces with a second height, wherein the second height is at least 1.5 times the first height,
wherein, at an interface between the first plurality of layers and the second plurality of layers, a hybrid bond joins the first plurality of layers and the second plurality of layers, wherein the hybrid bond comprises one or more direct bonds between one or more conductive traces of the first plurality of layers and one or more conductive traces of the second plurality of layers.

2. The device of claim 1, wherein the first plurality of layers comprises a substrate core, wherein one or more vias are defined in the substrate core, wherein individual vias of the one or more vias extend from a top surface of the substrate core to a bottom surface of the substrate core.

3. The device of claim 2, wherein individual vias of the one or more vias are filled with a magnetic lining surrounding a conductive material.

4. The device of claim 1, wherein the substrate does not include a substrate core, wherein one or more vias are defined through the first plurality of layers and the second plurality of layers, wherein individual vias of the one or more vias are filled with a magnetic material.

5. The device of claim 1, wherein one or more vias are defined in the substrate, wherein individual vias of the one or more vias are at least partially filled with a magnetic material.

6. The device of claim 5, wherein the magnetic material has a relative permeability over 100.

7. The device of claim 5, further comprising a die mounted on the substrate, wherein the substrate comprises one or more traces that are to provide power to the die.

8. The device of claim 7, wherein the magnetic material stabilizes a voltage and/or current provided by the one or more traces that are to provide power to the die.

9. The device of claim 1, wherein the hybrid bond further comprises a dielectric bond between a dielectric material of the first plurality of layers and a dielectric material of the second plurality of layers.

10. The device of claim 9, wherein the hybrid bond further comprises a bond between one or more conductive traces of the first plurality of layers and the dielectric material of the second plurality of layers.

11. The device of claim 9, wherein the dielectric material comprises carbon and hydrogen.

12. The device of claim 1, wherein the first height is between 12 and 18 micrometers, wherein the second height is between 22 and 28 micrometers.

13. A device comprising:
a substrate comprising:
a first plurality of layers, wherein individual layers of the first plurality of layers comprises a plurality of conductive traces with a first height; and
a second plurality of layers adjacent the first plurality of layers, wherein individual layers of the second plurality of layers comprises a plurality of conductive traces with a second height, wherein the second height is at least 1.5 times the first height,
means for joining the first plurality of layers and the second plurality of layers.

14. The device of claim 13, wherein the means for joining the first plurality of layers and the second plurality of layers comprises a copper-copper fusion bond.

15. The device of claim 13, further comprising a die mounted on the substrate, wherein the substrate comprises one or more traces that are to provide power to the die, wherein the substrate further comprises means for increasing an inductance of the one or more traces that are to provide power to the die.

16. A method comprising:
forming a first plurality of layers for a substrate, wherein forming the first plurality of layers comprises forming a plurality of conductive traces with a first height;
forming a second plurality of layers for the substrate, wherein forming the first plurality of layers comprises forming a plurality of conductive traces with a second height, wherein the second height is at least 1.5 times the first height; and
joining the first plurality of layers to the second plurality of layers using hybrid bonding.

17. The method of claim 16, wherein forming the first plurality of layers comprises forming the first plurality of layers on a substrate core.

18. The method of claim 17, further comprising:
forming one or more vias in the substrate core;
forming a magnetic lining in the substrate core; and
filling the magnetic lining with a conductive material.

19. The method of claim 16, wherein forming the first plurality of layers comprises:
forming the first plurality of layers on a glass carrier; and
separating the first plurality of layers from the glass carrier.

20. The method of claim 19, further comprising:
drilling one or more vias through the first plurality of layers;
filling the one or more vias through the first plurality of layers with a magnetic material;
drilling one or more vias through the second plurality of layers; and
filling the one or more vias through the second plurality of layers with a magnetic material.
